(19) United States
(12) Patent Application Publication
(10) Pub. No.: US 2026/0341815 A1
(43) Pub. Date: Oct. 29, 2026

(54) CONTROLLERS FOR IMPLEMENTING A DIAGNOSTIC PROFILE FOR AN ELECTROCHEMICAL CELL ASSEMBLY, AND ASSOCIATED METHODS

(71) Applicant: Element Energy, Inc., Menlo Park, CA (US)

(72) Inventors: Corrado Cammi, Mountain View, CA (US); Maxwell Lee Wood, Los Angeles, CA (US); Anthony John Stratakos, Carmel, CA (US); Yoosok Saw, Mountain View, CA (US)

(21) Appl. No.: 19/193,812

(22) Filed: Apr. 29, 2025

(51) Int. Cl. H01M 10/44; G01R 31/3842; G01R 31/392; H02J 7/82; H02J 7/84; H02J 7/94; H02J 7/96

(52) U.S. Cl. CPC H01M 10/44; G01R 31/3842; G01R 31/392; H02J 7/82; H02J 7/84; H02J 7/94; H02J 7/96; H02J 2207/20

(57) ABSTRACT

A method for implementing a diagnostic profile for an electrochemical cell assembly includes (i) dividing a complete diagnostic profile for the electrochemical cell assembly into a plurality of diagnostic profile segments, the plurality of diagnostic profile segments including at least a first diagnostic profile segment and a second diagnostic profile segment, and (ii) controlling operation of the electrochemical cell assembly to implement each of the plurality of diagnostic profile segments such that at least the first diagnostic profile segment and the second diagnostic profile segment are implemented during different respective operating intervals of the electrochemical cell assembly.

### BACKGROUND

Many electrochemical cells, such as Lithium-ion (Li-ion) electrochemical cells, may be charged and discharged multiple times. However, electrochemical cells tend to degrade with use as well as with time. Accordingly, an electrochemical cell that has been in service for an extended period may have a lower state of health (SOH), a higher state of degradation (SOD), and/or a lower state of safety (SOS), than a new electrochemical cell of like type. Additionally, an electrochemical cell may be defective and therefore have a lower SOH, a higher SOD, and/or a lower SOS than the electrochemical cell would if it were not defective.

Many energy storage systems include electrochemical cells for energy storage. An energy storage system may be used, for example, to supplement generation capacity in an electric power grid, to provide backup electric power to a load in case of failure of a primary electric power source, or to store energy from an intermittently available electric power source for use when the intermittently available electric power source is unavailable.

### SUMMARY

Disclosed herein are new controllers and methods for implementing a diagnostic profile for an electrochemical cell assembly. The new controllers and methods divide a complete diagnostic profile into a plurality of diagnostic profile segments, and at least two of the diagnostic profile segments are implemented during different respective electrochemical cell operating intervals, such as during different charging intervals and/or different discharging intervals. Additionally, measurement characteristics of the electrochemical cell assembly are obtained during implementation of each of the diagnostic profile segments, and the obtained measurement characteristics are combined to generate a complete measurement set representing characteristics of the electrochemical cell assembly over the complete diagnostic profile.

In an embodiment, a method for implementing a diagnostic profile for an electrochemical cell assembly includes (i) dividing a complete diagnostic profile for the electrochemical cell assembly into a plurality of diagnostic profile segments, the plurality of diagnostic profile segments including at least a first diagnostic profile segment and a second diagnostic profile segment, and (ii) controlling operation of the electrochemical cell assembly to implement each of the plurality of diagnostic profile segments such that at least the first diagnostic profile segment and the second diagnostic profile segment are implemented during different respective operating intervals of the electrochemical cell assembly.

In another embodiment, a method for implementing a diagnostic profile for an electrochemical cell assembly includes (i) at a first time, controlling operation of the electrochemical cell assembly during a first operating interval of the electrochemical cell assembly to begin implementing a diagnostic profile for the electrochemical cell assembly, (ii) at a second time that is after the first time, controlling operation of the electrochemical cell assembly during the first operating interval of the electrochemical cell assembly to stop implementation of the diagnostic profile before implementation of the diagnostic profile is complete, and (iii) at a third time that is after the second time, controlling operation of the electrochemical cell assembly during a second operating interval of the electrochemical cell assembly to resume implementation of the diagnostic profile.

In another embodiment, a controller for implementing a diagnostic profile for an electrochemical cell assembly includes a storage subsystem and a processing subsystem communicatively coupled to each of the storage subsystem and one or more power converters. The one or more power converters are configured to control operation of the electrochemical cell assembly. The processing subsystem is configured to execute instructions stored in the storage subsystem to (i) divide a complete diagnostic profile for the electrochemical cell assembly into a plurality of diagnostic profile segments, the plurality of diagnostic profile segments including at least a first diagnostic profile segment and a second diagnostic profile segment, and (ii) control the one or more power converters to control operation of the electrochemical cell assembly to implement each of the plurality of diagnostic profile segments such that at least the first diagnostic profile segment and the second diagnostic profile segment are implemented during different respective operating intervals of the electrochemical cell assembly.

### BRIEF DESCRIPTION OF THE DRAWINGS

FIG. 1 is a schematic diagram of an electrical environment including a controller for implementing a diagnostic profile of an electrochemical cell assembly, according to an embodiment.

FIG. 2 is a schematic diagram of one example embodiment of an electrochemical cell assembly of the FIG. 1 electrical environment.

FIG. 3 is a schematic diagram of another example embodiment of an electrochemical cell assembly of the FIG. 1 electrical environment.

FIG. 4 is a schematic diagram of an additional example embodiment of an electrochemical cell assembly of the FIG. 1 electrical environment.

FIG. 5 is a schematic diagram of a further example embodiment of an electrochemical cell assembly of the FIG. 1 electrical environment.

FIG. 6 is a block diagram of the controller of the FIG. 1 electrical environment.

FIG. 7 is an illustration of an example embodiment of a complete diagnostic profile.

FIG. 8 is an illustration of an example embodiment of a set of diagnostic profile segments.

FIG. 9 is a graph of state of charge versus time illustrating an example of implementation of the FIG. 8 diagnostic profile segments during charging of the FIG. 1 electrochemical cell assembly.

FIG. 10 is a graph of state of charge versus time illustrating an example of implementation of the FIG. 8 diagnostic profile segments during discharging of the FIG. 1 electrochemical cell assembly.

FIG. 11 is a timing diagram illustrating one example of the FIG. 1 controller implementing diagnostic profile segments over a plurality of charging intervals of the FIG. 1 electrochemical cell assembly.

FIG. 12 is a timing diagram illustrating another example of the FIG. 1 controller implementing diagnostic profile segments over a plurality of charging intervals of the FIG. 1 electrochemical cell assembly.

FIG. 13 is a timing diagram illustrating one example of the FIG. 1 controller implementing diagnostic profile segments over a plurality of discharging intervals of the FIG. 1 electrochemical cell assembly.

FIG. 14 is a timing diagram illustrating another example of the FIG. 1 controller implementing diagnostic profile segments over a plurality of discharging intervals of the FIG. 1 electrochemical cell assembly.

FIG. 15 is a timing diagram illustrating one example of the FIG. 1 controller implementing diagnostic profile segments over a plurality of charging intervals of the FIG. 1 electrochemical cell assembly where implementation of a diagnostic profile segment is stopped before its implementation is complete.

FIG. 16 is a timing diagram illustrating another example of the FIG. 1 controller implementing diagnostic profile segments over a plurality of charging intervals of the FIG. 1 electrochemical cell assembly where implementation of a diagnostic profile segment is stopped before its implementation is complete.

FIG. 17 illustrates an example embodiment of a set of measurement characteristics.

FIG. 18 illustrates an example embodiment of a complete measurement set.

FIG. 19 is a flow chart of a method for implementing a diagnostic profile for an electrochemical cell assembly, according to an embodiment.

FIG. 20 is a flow chart of another method for implementing a diagnostic profile for an electrochemical cell assembly, according to an embodiment.

FIG. 21 is a schematic diagram of an embodiment of the FIG. 1 electrical environment where a power converter is embodied by a direct-current-to-direct-current (DC-to-DC) converter.

FIG. 22 is a schematic diagram of an embodiment of the FIG. 1 electrical environment where a power converter is embodied by an inverter.

FIG. 23 is a schematic diagram of an electrical environment including a plurality of battery management system (BMS) nodes of FIG. 1, according to an embodiment.

FIG. 24 is a schematic diagram of an alternate embodiment of the FIG. 23 electrical environment including a plurality of BMS nodes electrically coupled in parallel.

### DETAILED DESCRIPTION OF THE EMBODIMENTS

State of health (SOH), state of degradation (SOD), and/or state of safety (SOS) of an electrochemical cell assembly may be determined by (i) implementing a diagnostic profile for the electrochemical cell assembly, (ii) obtaining one or more measurement characteristics of the electrochemical cell assembly during implementation of the diagnostic profile, and (iii) analyzing the measurement characteristics. Implementation of a diagnostic profile for an electrochemical cell assembly typically requires causing the electrochemical cell assembly to operate at one or more predetermined diagnostic operating conditions during a charge interval or a discharge interval of the electrochemical cell assembly. These diagnostic operating conditions are typically different from normal operating conditions of the electrochemical cell assembly. For example, a diagnostic profile may specify that the electrochemical cell assembly operates at a different charge/discharge rate, different current level, different voltage level, and/or different power level, than the electrochemical cell would normally operate at. As such, implementation of a diagnostic profile may interfere with ability of the electrochemical cell assembly to serve its intended purpose, such as to supplement generation capacity, provide a backup electric power source, or store energy from an intermittently available electric power source. Additionally, many diagnostic profiles must be implemented over a significant portion of an electrochemical cell assembly's charge interval or discharge interval. Consequently, conventional implementation of a diagnostic profile for an electrochemical cell assembly may prevent normal use of the electrochemical cell assembly for an extended period. Therefore, it is frequently infeasible to implement a diagnostic profile using conventional approaches in applications where extended downtime of an electrochemical cell assembly is unacceptable.

Disclosed herein are new controllers and methods for implementing a diagnostic profile for an electrochemical cell assembly which at least partially overcome the above discussed drawbacks of conventional approaches to implementing a diagnostic profile. The new controllers and methods divide a complete diagnostic profile into a plurality of diagnostic profile segments, and at least two of the diagnostic profile segments are implemented during different respective electrochemical cell operating intervals, such as during different charging intervals and/or different discharging intervals. Additionally, measurement characteristics of the electrochemical cell assembly are obtained during implementation of each of the diagnostic profile segments, and the obtained measurement characteristics are combined to generate a complete measurement set representing characteristics of the electrochemical cell assembly over the complete diagnostic profile. As such, the new controllers and methods enable implementation of a diagnostic profile to be spread over multiple charging and/or discharging intervals, thereby helping minimize impact of implementing the diagnostic profile during any given charging or discharging interval. Therefore, the new controllers and methods may enable a diagnostic profile to be implemented without significantly interfering with normal operation of electrochemical cell assembly. Accordingly, the new controllers and methods enable implementation of a diagnostic profile in applications where it would be infeasible to implement a diagnostic profile using conventional approaches, such as in applications where extended downtime of an electrochemical cell assembly is unacceptable.

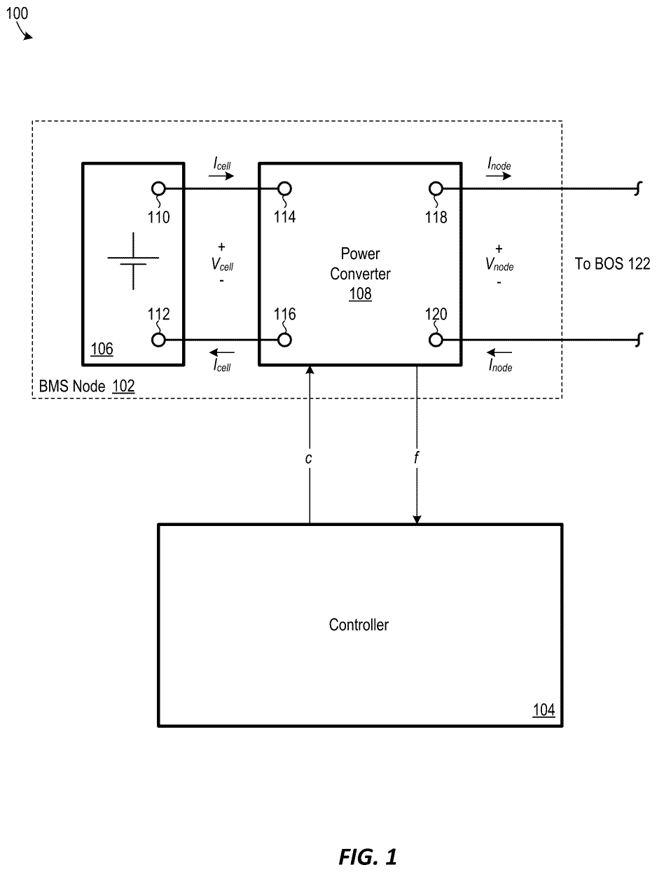

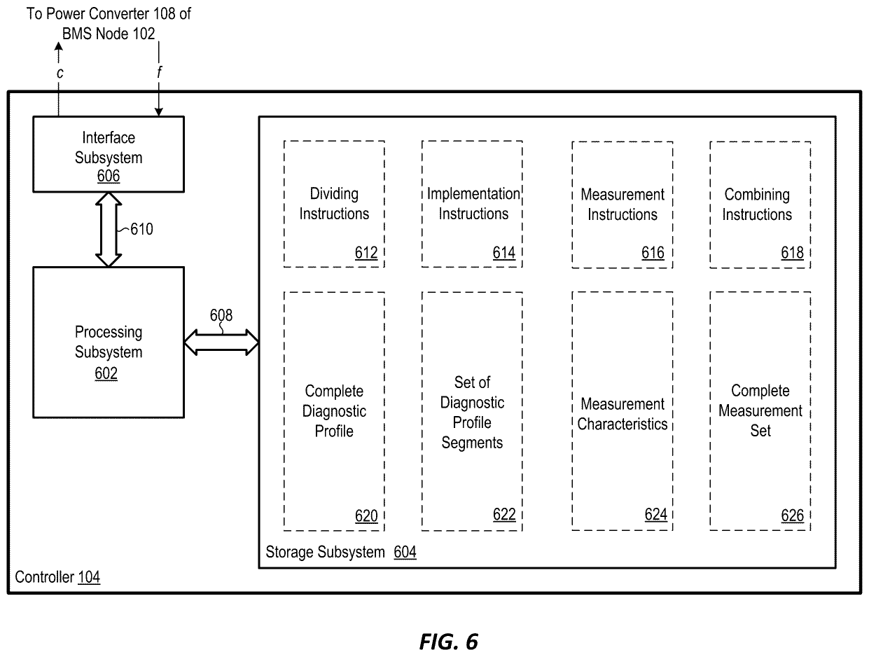

FIG. 1 is a schematic diagram of an electrical environment 100 including a battery management system (BMS) node 102 and a controller 104, where controller 104 is one embodiment of the new controllers for implementing a diagnostic profile for an electrochemical cell assembly. Details of controller 104 are not shown in FIG. 1 for illustrative clarity, although FIG. 6, discussed below, includes details of controller 104.

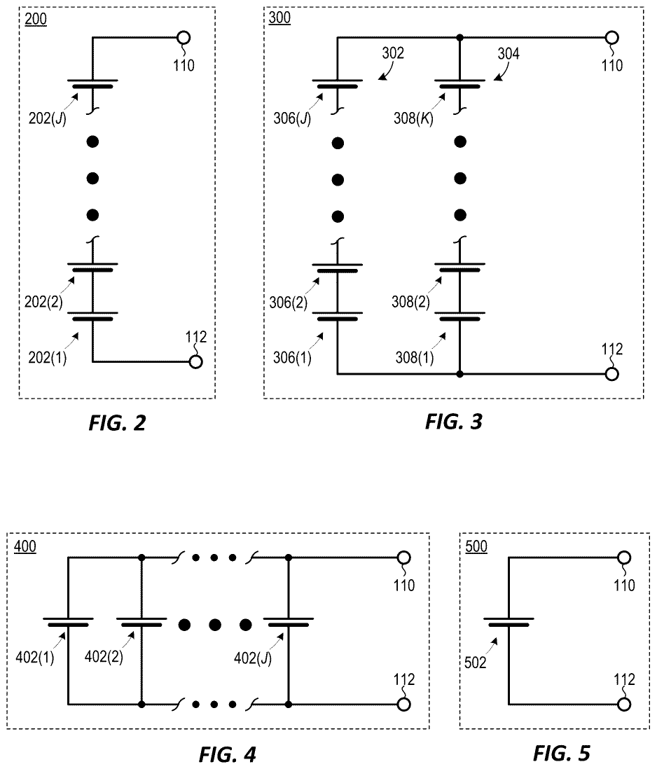

BMS node 102 includes an electrochemical cell assembly 106 and a power converter 108. Electrochemical cell assembly 106 includes one or more electrochemical cells, such as one or more Lithium-ion (Li-ion) electrochemical cells, electrically coupled between a positive cell assembly port 110 and a negative cell assembly port 112. The quantity of electrochemical cells in electrochemical cell assembly 106 could range from a single electrochemical cell to many electrochemical cells, such as tens, hundreds, thousands, tens of thousands, or more, electrochemical cells. Additionally, the elements of electrochemical cell assembly 106 need not be co-packaged. For example, in some embodiments, electrochemical cell assembly 106 includes multiple containers that are physically separate but are electrically coupled together, where each container includes a large quantity of electrochemical cells. FIGS. 2-5, discussed below, illustrate several example embodiments of electrochemical cell assembly 106, although it is understood that electrochemical cell assembly 106 is not limited to the example embodiments of FIGS. 2-5.

FIG. 2 is a schematic diagram of an electrochemical cell assembly 200, which is one example embodiment of electrochemical cell assembly 106. Electrochemical cell assembly 200 includes J electrochemical cells 202 electrically coupled in a series string between positive cell assembly port 110 and negative cell assembly port 112, where J is an integer greater than one. In this document, specific instances of an item may be referred to by use of a numeral in parentheses (e.g. electrochemical cell 202(1)) while numerals without parentheses refer to any such item (e.g. electrochemical cells 202). In certain embodiments, each electrochemical cell 202 is a Li-ion electrochemical cell.

FIG. 3 is a schematic diagram of an electrochemical cell assembly 300, which is another example embodiment of electrochemical cell assembly 106. Electrochemical cell assembly 300 includes a first string 302 and a second string 304 electrically coupled in parallel within electrochemical cell assembly 300. String 302 includes J electrochemical cells 306 electrically coupled in series between positive cell assembly port 110 and negative cell assembly port 112, and string 304 includes K electrochemical cells 308 electrically coupled in series between positive cell assembly port 110 and negative cell assembly port 112. Each of J and K is an integer greater than one, and while not required, it is anticipated that K will normally be equal to J. In certain embodiments, each of electrochemical cell 306 and electrochemical cell 308 is a Li-ion electrochemical cell or a group of parallel-connected Li-ion electrochemical cells. Electrochemical cell assembly 300 could be modified to include one or more additional strings of series-coupled electrochemical cells. Additionally, electrochemical cell assembly 300 could be modified to include one or more additional electrochemical cells electrically coupled in parallel with each electrochemical cell 306, as well as to include one or more additional electrochemical cells electrically coupled in parallel with each electrochemical cell 308.

FIG. 4 is a schematic diagram of an electrochemical cell assembly 400, which is another example embodiment of electrochemical cell assembly 106. Electrochemical cell assembly 400 includes J electrochemical cells 402 electrically coupled in parallel between positive cell assembly port 110 and negative cell assembly port 112, where J is an integer greater than one. In certain embodiments, each electrochemical cell 402 is a Li-ion electrochemical cell. FIG. 5 is a schematic diagram of an electrochemical cell assembly 500, which is yet another example embodiment of electrochemical cell assembly 106. Electrochemical cell assembly 500 includes a single electrochemical cell 502 electrically coupled between positive cell assembly port 110 and negative cell assembly port 112. In some embodiments, electrochemical cell 502 is a Li-ion electrochemical cell.

Referring again to FIG. 1, power converter 108 includes a positive input port 114, a negative input port 116, a positive output port 118, and a negative output port 120. Power converter 108 is electrically coupled to electrochemical cell assembly 106 via positive input port 114 and negative input port 116. Specifically, positive input port 114 is electrically coupled to positive cell assembly port 110, and negative input port 116 is electrically coupled to negative cell assembly port 112. Power converter 108 is electrically coupled to a balance of system (BOS) 122 (not shown) via positive output port 118 and negative output port 120. Balance of system 122 includes, for example, one or more additional BMS nodes, a load, an energy source, switches, and/or one or more other power converters (e.g., an inverter and/or a direct-current-to-direct-current (DC-to-DC) converter).

Power converter 108 is configured to control operation of electrochemical cell assembly 106 by converting a voltage V_{cell} across electrochemical cell assembly 106 to a voltage V_{node} between positive output port 118 and negative output port 120 (or vice versa). Additionally, power converter 108 is configured to control operation of electrochemical cell assembly 106 by converting a current I_{cell} flowing through electrochemical cell assembly 106 to a current I_{node} flowing between positive output port 118 and negative output port 120 (or vice versa). Power converter 108 is at least partially controlled by controller 104 via control signals c from controller 104, as discussed below. Additionally, power converter 108 may be partially controlled by one or more one additional controllers (not shown). Power converter 108 is also configured to provide feedback signals f to controller 104, where feedback signals f represent one or more parameters of BMS node 102. Examples of possible parameters represented by feedback signals f include, but are not limited to, one or more of voltage V_{cell}, current I_{cell}, voltage V_{node}, current I_{node}, and temperature T_{cell} of electrochemical cell assembly 106. Control signals c and feedback signals f are communicatively coupled between power converter 108 and controller 104, for example, via one or more electrical communication links (not shown), one or more optical communication links (e.g., an optical cable communication link or a free space optical communication link) (not shown), and/or one more radio frequency (RF) communications links (e.g., a waveguide RF communication link or a free space RF communication link) (not shown).

Power converter 108 is, for example, a DC-to-DC converter or an inverter. In some embodiments, power converter 108 includes one or more of a boost converter, a buck converter, a buck-boost converter, a buck and boost converter, a flyback converter, a forward converter, a full bridge converter, a half bridge converter, a linear regulator, a Cúk converter, a resonant converter, or a switched capacitor converter. In certain embodiments, power converter 108 includes two or more power converters electrically coupled in series and/or in parallel. Certain embodiments of power converter 108 are galvanically isolated, e.g., positive input port 114 and negative input port 116 are galvanically isolated from positive output port 118 and negative output port 120. In some other embodiments, power converter 108 is non-isolating. Additionally, in certain embodiments, each of positive input port 114, negative input port 116, positive output port 118, and negative output port 120 is part of a different respective electrical node, while in some other embodiments, at least two of the aforementioned ports are part of a common electrical node. For example, in certain embodiments, negative input port 116 and negative output port 120 are part of a common electrical node, such as a reference node.

Controller 104 is configured to control power converter 108 via control signals c to control charging of electrochemical cell assembly 106, and/or discharging of electrochemical cell assembly 106, to implement a diagnostic profile for electrochemical cell assembly 106. Additionally, controller 104 is configured to control power converter 108 via control signals c to control charging and/or discharging of electrochemical cell assembly 106 such that the diagnostic profile may be implemented over two or more different operating intervals of electrochemical cell assembly 106, such as over two or more charging intervals of electrochemical cell assembly 106 and/or over two or more discharging intervals of electrochemical cell assembly 106, as discussed below. Controller 104 is optionally further configured to control power converter 108 via control signals c for purposes other than implementing a diagnostic profile, such as to control charging and discharging of electrochemical cell assembly 106 during normal operation of electrochemical cell assembly 106, to control charging and discharging of electrochemical cell assembly 106 to mitigate degradation of electrochemical cell assembly 106, and/or to control charging and discharging of electrochemical cell assembly 106 to mitigate an unsafe condition in electrochemical cell assembly 106.

FIG. 6 is a block diagram of controller 104. As illustrated in FIG. 6, controller 104 includes a processing subsystem 602, a storage subsystem 604, and an interface subsystem 606. Processing subsystem 602 is communicatively coupled with storage subsystem 604 as symbolically shown by an arrow 608, and processing subsystem 602 is communicatively coupled with interface subsystem 606 as symbolically shown by an arrow 610. The elements of controller 104 may be co-packaged, e.g., on a single circuit board or in a single integrated circuit, or they may be separated from each other. Additionally, one or more elements of controller 104 could implemented by two or more sub-elements that need not be co-located. For example, processing subsystem 602 could be implemented by one or more processors (not shown) which need not be co-located. As another example, storage subsystem 604 could be implemented by two or more memories and/or two or more data storage drives which need not be co-located. In some embodiments, controller 104 is at least partially embodied by a distributed computing system, such as a cloud computing system. Additionally, controller 104 could alternately be at least partially integrated with BMS node 102 without departing from the scope hereof.

Interface subsystem 606 is configured to communicatively interface controller 104 with power converter 108 of BMS node 102 such that processing subsystem 602 is communicatively coupled to power converter 108. Interface subsystem 606 is optionally also configured to communicatively interface controller 104 with one or more other elements (not shown), e.g., additional BMS nodes, one or more other controllers, an external data source, a user interface, etc. Interface subsystem 606 is configured, for example, to perform signal level shifting, perform signal protocol translation, and/or perform signal domain conversion (e.g., to convert signals between an electrical domain and an optical domain, to convert signals between an electrical domain and an RF wireless domain, to convert signals between an optical domain and a RF wireless domain, etc.).

Storage subsystem 604 stores instructions for execution by processing subsystem 602 to perform functions of controller 104. Storage subsystem 604 also stores data for use by processing subsystem 602 and/or data generated by processing subsystem 602. FIG. 6 illustrates storage subsystem 604 as storing the following instructions: (i) dividing instructions 612, (ii) implementation instructions 614, (iii) measurement instructions 616, and (iv) combining instructions 618. FIG. 6 also illustrates storage subsystem 604 as storing the following data: (i) a complete diagnostic profile 620, (ii) a set 622 of a plurality of diagnostic profile segments, (iii) measurement characteristics 624, and (iv) a complete measurement set 626. However, storage subsystem 604 could be modified to store additional, fewer, and/or alternative instructions and/or data. Additionally, controller 104 could be modified to implement some or all functionality of controller 104 using digital electronic circuitry and/or analog electronic circuitry in addition to, or in place of, processing subsystem 602 and storage subsystem 604.

Complete diagnostic profile 620 includes a plurality of predetermined diagnostic operating conditions for electrochemical cell assembly 106 to be implemented on electrochemical cell assembly 106 for the purpose of performing one or more diagnostic tests on electrochemical cell assembly 106. Examples of the diagnostic tests include, but are not limited to, diagnostic tests for determining SOH, SOD, and/or SOH of electrochemical cell assembly 106. For instance, in embodiments where electrochemical cell assembly 106 includes one or more Li-ion electrochemical cells, complete diagnostic profile 620 may specify a plurality of diagnostic operating conditions for the purpose of determining one or more of (a) loss of Lithium inventory in one or more electrochemical cells of electrochemical cell assembly 106, (b) growth of anode impedance in one or more electrochemical cells of electrochemical cell assembly 106, (c) growth of cathode impedance in one or more electrochemical cells of electrochemical cell assembly 106, (d) loss of anode active material in one or more electrochemical cells of electrochemical cell assembly 106, (e) loss of cathode active material in one or more electrochemical cells of electrochemical cell assembly 106, (f) abnormal anode Lithiation level in one or more electrochemical cells of electrochemical cell assembly 106, (g) abnormal cathode Lithiation level in one or more electrochemical cells of electrochemical cell assembly 106, (h) Lithium plating on electrodes in one or more electrochemical cells of electrochemical cell assembly 106, (i) mechanical shorting in one or more electrochemical cells of electrochemical cell assembly 106, and (j) gas evolution in one or more electrochemical cells of electrochemical cell assembly 106.

Each diagnostic operating condition specified by complete diagnostic profile 620 specifies one or more of the following: (i) a respective rate of charge or discharge of electrochemical cell assembly 106, (ii) a respective operating current level of electrochemical cell assembly 106, where operating current level of electrochemical cell assembly 106 is magnitude of current I_{cell} flowing through electrochemical cell assembly 106, (iii) a respective operating power level of electrochemical cell assembly 106, where operating power level of electrochemical cell assembly 106 is magnitude of a product of current I_{cell} flowing through electrochemical cell assembly 106 and voltage V_{cell} across electrochemical cell assembly 106, and (iv) a respective operating voltage level of electrochemical cell assembly 106, where operating voltage level of electrochemical cell assembly 106 is magnitude of voltage V_{cell} across electrochemical cell assembly 106. It should be noted that a diagnostic operating condition may be a rest state where magnitude of current I_{cell} is zero such that electrochemical cell assembly 106 is neither being charged nor discharged. Each diagnostic operating condition of complete diagnostic profile 620 is intended to be implemented at a different respective state of charge range of electrochemical cell assembly 106. While not required, it is anticipated that each diagnostic operating condition specified by diagnostic profile 620 will typically be different from a normal operating condition of electrochemical cell assembly 106 at a state of charge range corresponding to the diagnostic operating condition. For example, assume that a diagnostic operating condition is intended to be implemented within a state of charge range of electrochemical cell assembly 106 ranging from forty percent state of charge to fifty percent state of charge. While not required, it is anticipated that the diagnostic operating condition intended be implemented between forty to fifty percent state of charge of electrochemical cell assembly 106 will be different from normal operation of electrochemical cell assembly 106 between forty to fifty percent state of charge.

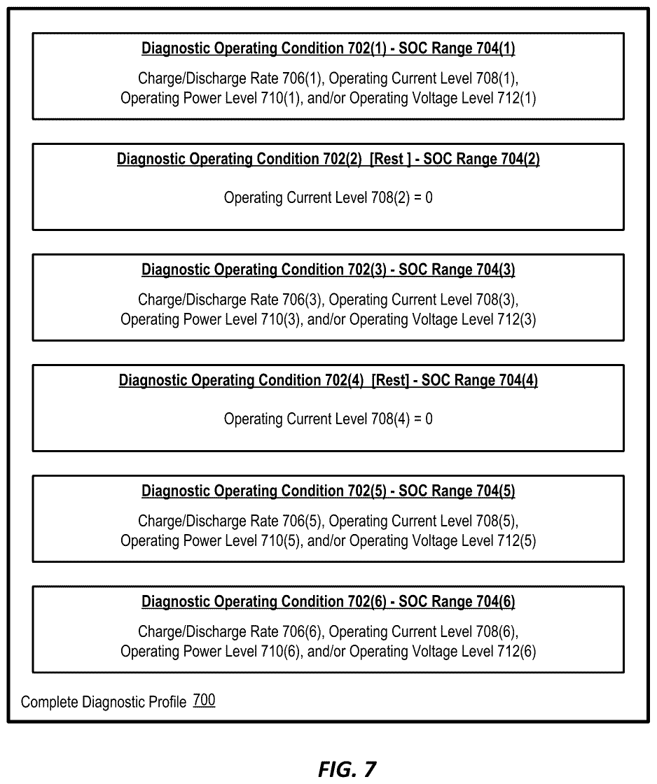

FIG. 7 illustrates a complete diagnostic profile 700, which is one embodiment of complete diagnostic profile 620 of FIG. 6, although it is understood that complete diagnostic profile 620 could be embodied in other manners. Complete diagnostic profile 700 includes six diagnostic operating conditions 702 for electrochemical assembly 106. Each diagnostic operating condition 702 is intended to be implemented at a different state of charge (SOC) range 704 of electrochemical cell assembly 106. Specifically, diagnostic operating condition 702(1) is intended to be implemented at a state of charge range 704(1) of electrochemical cell assembly 106, diagnostic operating condition 702(2) is intended to be implemented at a state of charge range 704(2) of electrochemical cell assembly 106, and so on. Additionally, each diagnostic operating condition 702 specifies one or more of the following: a respective charge or discharge rate 706 of electrochemical cell assembly 106, a respective operating current level 708 of electrochemical cell assembly 106, a respective operating power level 710 of electrochemical cell assembly 106, and a respective operating voltage level 712 of electrochemical cell assembly 106. For example, diagnostic operating condition 702(1) specifies one or more of a respective charge or discharge rate 706(1) of electrochemical cell assembly 106, a respective operating current level 708(1) of electrochemical cell assembly 106, a respective operating power level 710(1) of electrochemical cell assembly 106, and a respective operating voltage level 712(1) of electrochemical cell assembly 106. As another example, diagnostic operating condition 702(3) specifies one or more of a respective charge or discharge rate 706(3) of electrochemical cell assembly 106, a respective operating current level 708(3) of electrochemical cell assembly 106, a respective operating power level 710(3) of electrochemical cell assembly 106, and a respective operating voltage level 712(3) of electrochemical cell assembly 106. Respective values of charge/discharge rate 706, operating current level 708, operating power level 710, or operating voltage level 712 of any two instances of diagnostic operating condition 702 may the same, or they may be different.

It should be noted that each diagnostic operating condition 702 need not specify the same type of parameter. For example, one diagnostic operating condition 702 of complete diagnostic profile 700 may specify a charge/discharge rate 706 of electrochemical cell assembly 106, while another diagnostic operating condition 702 of electrochemical cell assembly 106 may specify an operating current level 708 of electrochemical cell assembly 106. Additionally, it should also be noted that each of diagnostic operating condition 702(2) and diagnostic operating condition 702(4) is a rest state. Accordingly, diagnostic operating condition 702(2) specifies that an operating current level 708(2) of electrochemical cell assembly 106 is zero, and diagnostic operating condition 702(4) specifies that an operating current level 708(4) of electrochemical cell assembly 106 is zero.

The quantity of diagnostic operating conditions 702 of complete diagnostic profile 700 may vary as a design choice. As such, while complete diagnostic profile 700 is illustrated as including six diagnostic operating conditions 702, complete diagnostic profile 700 could contain fewer than six diagnostic operating conditions 702, or complete diagnostic profile 700 could contain more than six diagnostic operating conditions 702. Additionally, the quantity of diagnostic operating conditions 702 that are rest states, as well as which diagnostic operating conditions 702 that are rest states, may vary as a design choice in complete diagnostic profile 700.

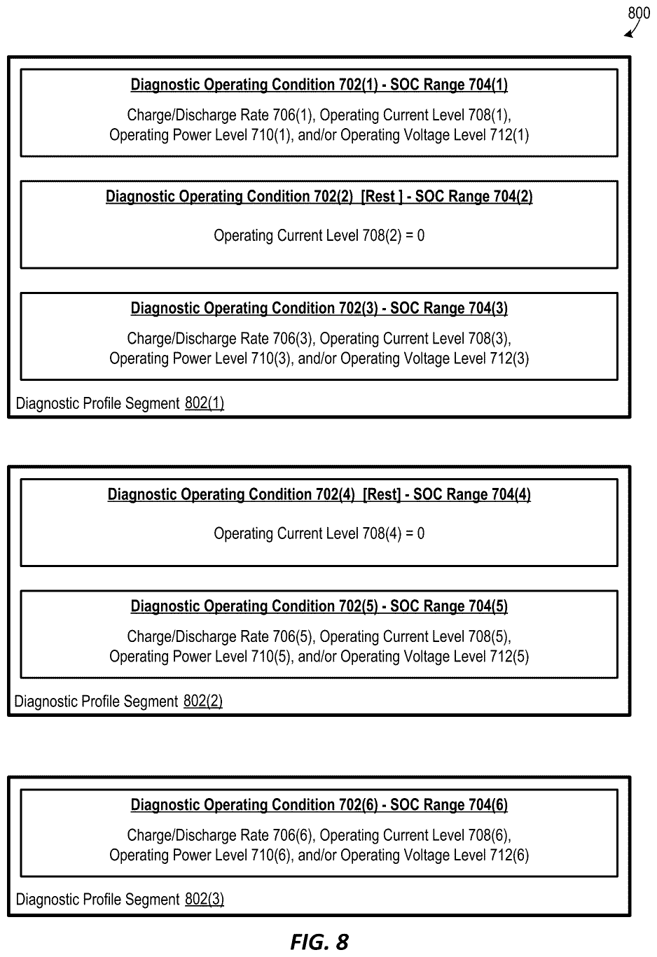

Referring again to FIG. 6, processing subsystem 602 is configured to execute dividing instructions 612 to divide complete diagnostic profile 620 into a set 622 of diagnostic profile segments. For example, FIG. 8 illustrates a set 800 of diagnostic profile segments 802, where set 800 is one example embodiment of set 622 of FIG. 6 and complete diagnostic profile 620 is embodied by complete diagnostic profile 700 of FIG. 7. Set 800 includes three diagnostic profile segments 802 which collectively encompass all diagnostic operating conditions 702 of complete diagnostic profile 700 of FIG. 7. Specifically, (i) a diagnostic profile segment 802(1) encompasses each of diagnostic operating conditions 702(1), 702(2), and 702(3), (ii) a diagnostic profile segment 802(2) encompasses each of diagnostic operating conditions 702(4) and 702(5), and (iii) a diagnostic profile segment 802(3) encompasses diagnostic operating condition 702(6). However, the quantity of diagnostic profile segments 802 of set 800, as well as the quantity and identify of respective diagnostic operating conditions 702 encompassed by each diagnostic profile segment 802, may vary as a design choice.

Referring again to FIG. 6, processing subsystem 602 is configured to execute implementation instructions 614 to implement each diagnostic profile segment of set 622 by causing electrochemical cell assembly 106 to operate according to the diagnostic operating condition(s) specified in the diagnostic profile segment. For example, assume that set 622 of diagnostic profiles is embodied by set 800 illustrated in FIG. 8. Processing subsystem 602 executes implementation instructions 614 to implement diagnostic profile segment 802(1) to cause electrochemical cell assembly 106 to (i) operate according to diagnostic operating condition 702(1) while electrochemical cell assembly 106 is within state of charge range 704(1), (ii) operate according to diagnostic operating condition 702(2) while electrochemical cell assembly 106 is within state of charge range 704(2), and (iii) operate according to diagnostic operating condition 702(3) while electrochemical cell assembly 106 is within state of charge range 704(3). Additionally, in this example, processing subsystem 602 executes implementation instructions 614 to implement diagnostic profile segment 802(2) to cause electrochemical cell assembly 106 to (i) operate according to diagnostic operating condition 702(4) while electrochemical cell assembly 106 is within state of charge range 704(4) and (ii) operate according to diagnostic operating condition 702(5) while electrochemical cell assembly 106 is within state of charge range 704(5). Furthermore, in this example, processing subsystem 602 executes implementation instructions 614 to implement diagnostic profile segment 802(3) to cause electrochemical cell assembly 106 to operate according to diagnostic operating condition 702(6) while electrochemical cell assembly 106 is within state of charge range 704(6).

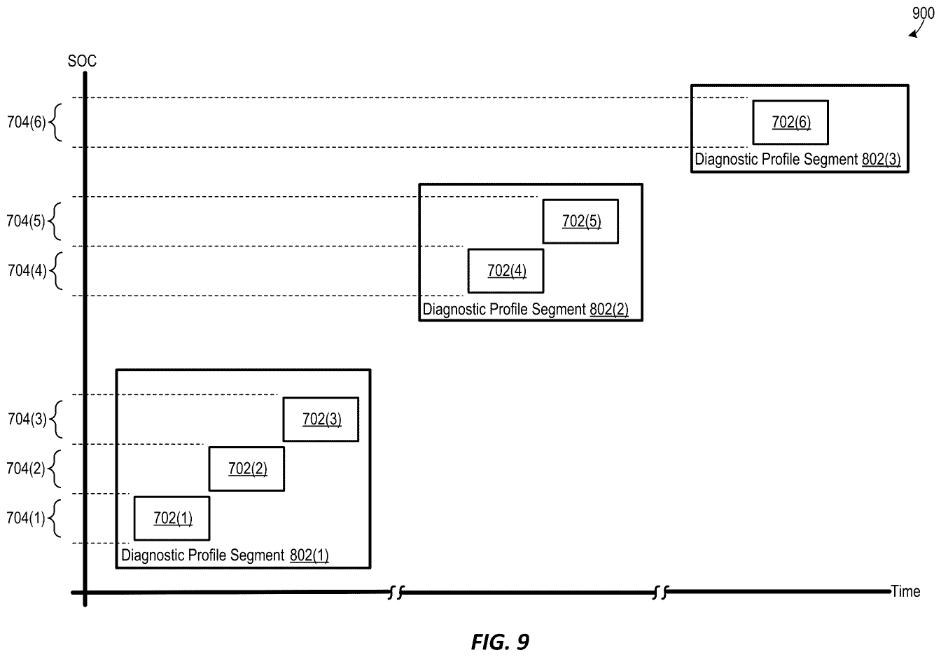

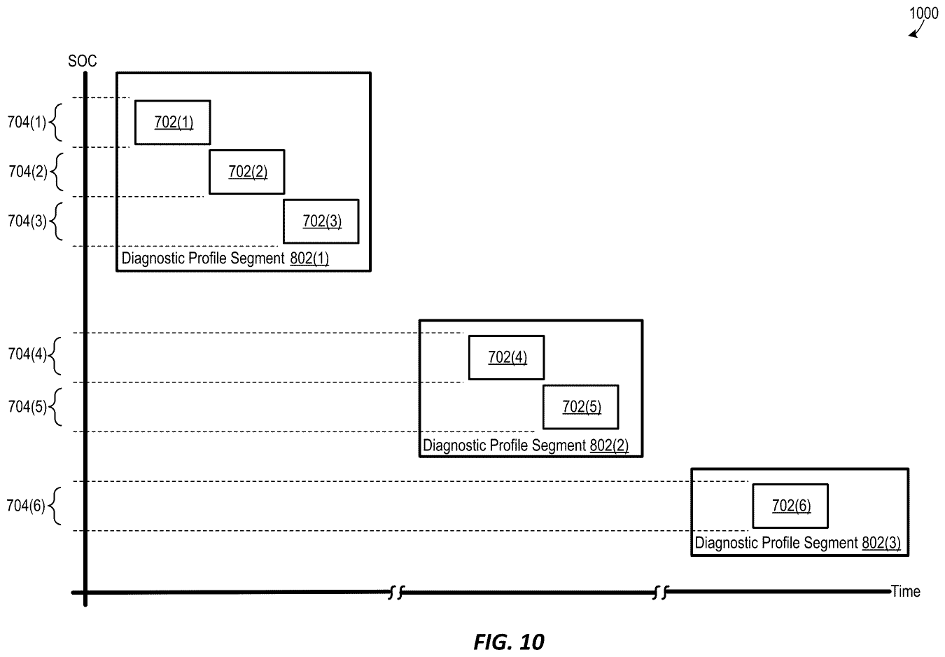

FIG. 9 is a graph 900 of state of charge versus time illustrating one example of processing subsystem 602 executing implementation instructions 614 to implement diagnostic profile segments 802 (FIG. 8) in an embodiment where complete diagnostic profile 620 is intended to be implemented during charging of electrochemical cell assembly 106. FIG. 10 is a graph 1000 of state of charge versus time illustrating one example of processing subsystem 602 executing implementation instructions 614 to implement diagnostic profile segments 802 in an embodiment where complete diagnostic profile 620 is intended to be implemented during discharging of electrochemical cell assembly 106. FIGS. 9 and 10 illustrate each diagnostic operating condition 702 being implemented during a respective state of charge range 704, where the actual values of each state of charge range 704 will differ according to whether complete diagnostic profile 620 is intended to be implemented during charging or discharging of electrochemical cell assembly 106. The horizontal axes in FIGS. 9 and 10 include multiple line segments to indicate that diagnostic profile segments 802 may be implemented during significantly different time periods, such as during different respective operating intervals of electrochemical cell assembly 106, as discussed below.

Referring again to FIGS. 1 and 6, processing subsystem 602 executes implementation instructions 614 to cause electrochemical cell assembly 106 to operate according to a given diagnostic operating condition by controlling operation of power converter 108 via control signals c to implement the diagnostic operating condition. For example, processing subsystem 602 executes implementation instructions 614 to cause electrochemical cell assembly 106 to operate according to diagnostic operating condition 702(1) by controlling operation of power converter 108 via control signals c to (i) cause a charge or discharge rate of electrochemical assembly 106 to be charge/discharge rate 706(1), (ii) cause magnitude of current I_{cell} to be operating current level 708(1), (iii) cause magnitude of product of current I_{cell} and voltage V_{cell} to be operating power level 710(1), and/or (iv) cause magnitude of voltage V_{cell} to be operating voltage level 712(1). As another example, processing subsystem 602 executes implementation instructions 614 to cause electrochemical cell assembly 106 to operate according to diagnostic operating condition 702(2) by controlling operation of power converter 108 via control signals c to cause current I_{cell} to be zero, such that electrochemical cell assembly 106 is neither charging nor discharging. In some embodiments, processing subsystem 602 executes implementation instructions 614 to cause electrochemical cell assembly 106 to operate according to a given diagnostic operating condition, such as a given diagnostic operating condition 702, in response to one or more criteria being met. Examples of the aforementioned criteria include, but are not limited to, one or more of (i) state of charge of electrochemical cell assembly 106 crossing a predetermined threshold value or being within a predetermined state of charge range, (ii) voltage V_{cell} across electrochemical cell assembly 106 crossing a predetermined threshold value or being within a predetermined voltage range, (iii) magnitude of current I_{cell} flowing through electrochemical cell assembly 106 crossing a predetermined threshold value or being within a predetermined current range, (iv) temperature of electrochemical cell assembly 106 crossing a threshold value or being with a predetermined temperature range, and (v) magnitude of power of electrochemical cell assembly 106, which is equal to the product of V_{cell} and I_{cell}, crossing a threshold value or being within a predetermined power range.

Importantly, processing subsystem 602 is configured to execute implementation instructions 614 to implement at least two diagnostic profile segments of set 622 during different respective operating intervals of electrochemical cell assembly 106, where an operating interval may be either (i) a charging interval of electrochemical cell assembly 106 where electrochemical cell assembly 106 is charged from energy received from balance of system 122 or (ii) a discharging interval of electrochemical cell assembly 106 where electrochemical cell assembly 106 discharges energy stored therein into one or more loads of balance of system 122. Such spreading of diagnostic profile segment implementation over two or more operating intervals advantageously helps minimize interference with normal operation of electrochemical cell assembly 106 during a given operating interval, thereby enabling implementation of complete diagnostic profile 620 in applications where extended downtime of electrochemical cell assembly 106 due to diagnostic profile implementation is unacceptable.

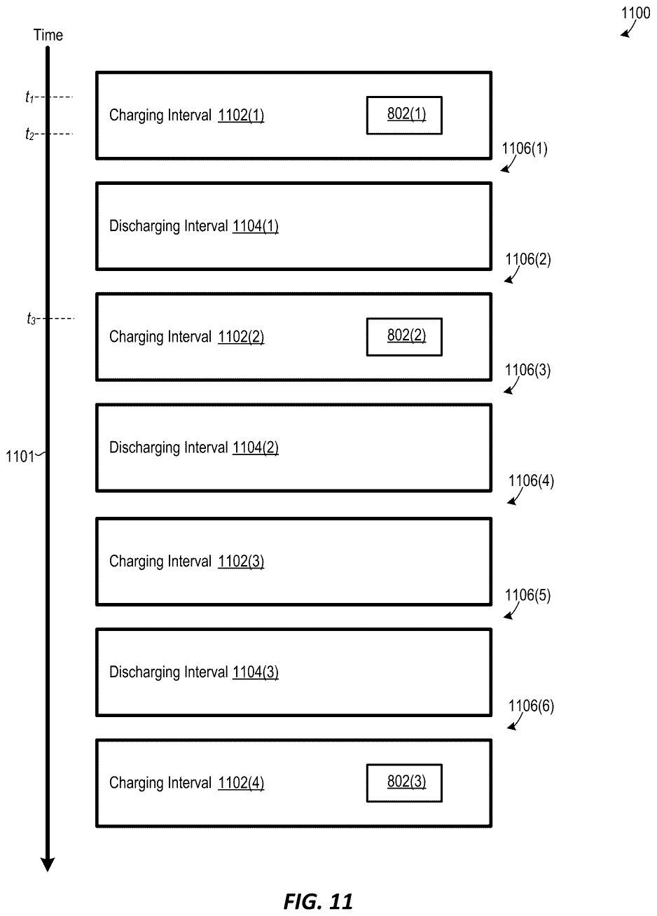

FIGS. 11-16 collectively illustrate several examples of how controller 104 may implement at least two diagnostic profile segments of set 622 during different respective operating intervals of electrochemical cell assembly 106. It is understood, though, that controller 104 is not limited to operating according to the examples of FIGS. 11-16. Additionally, FIGS. 11-16 assume that (i) complete diagnostic profile 620 of FIG. 6 is embodied by complete diagnostic profile 700 of FIG. 7 and (ii) complete diagnostic profile 700 is divided into diagnostic profile segments 802 of FIG. 8. It is understood, though, that the examples of FIGS. 11-16 could be adapted to other embodiments of complete diagnostic profile 620 as well as to other divisions of complete diagnostic profile 620 into diagnostic profile segments.

FIGS. 11-16 include a plurality of charging intervals and a plurality of discharging intervals. It should be noted that electrochemical cell assembly 106 need not be continuously charged during a charging interval. Instead, a given charging interval may include one or more idle periods where magnitude of current I_{cell} flowing through electrochemical cell assembly 106 is zero. For example, in certain embodiments, electrochemical cell assembly 106 may operate in an idle mode between successive implementations of diagnostic profile segments within a given charging interval. Additionally, electrochemical cell assembly 106 need not transition from a fully discharged state to a fully charged during a given charging interval. For example, electrochemical cell assembly 106 could transition from ten percent state of charge to ninety percent state of charge during a charging interval. As another example, electrochemical cell assembly 106 could transition from zero percent state of charge to seventy percent state of charge during a charging interval. As an additional example, electrochemical cell assembly 106 could transition from fifteen percent state of charge to one hundred percent state of charge during a charging interval.

Similarly, a given discharging interval may include one or more idle periods where magnitude of current I_{cell} electrochemical cell assembly 106 is zero. For example, in certain embodiments, electrochemical cell assembly 106 may operate in an idle mode between successive implementations of diagnostic profile segments within a given discharging interval. Additionally, electrochemical cell assembly 106 need not transition from a fully charged state to a fully discharged during a discharging interval. For example, electrochemical cell assembly 106 could transition from ninety-five percent state of charge to ten percent state of charge during a discharging interval. As another example, electrochemical cell assembly 106 could transition from eighty percent state of charge to zero percent state of charge during a discharging interval. As an additional example, electrochemical cell assembly could transition from one hundred percent state of charge to five percent state of charge during a discharging interval.

FIG. 11 is a timing diagram 1100 illustrating one example of controller 104 implementing diagnostic profile segments 802 over a plurality of charging intervals of electrochemical cell assembly 106. Increasing time is shown by an arrow 1101 in FIG. 11, and FIG. 11 illustrates alternating charging internals 1102 and discharging intervals 1104 of electrochemical cell assembly 106. FIG. 11 illustrates each charging interval 1102 being separated in time from a subsequent discharging interval 1104 by an idle period 1106 of electrochemical cell assembly 106 where magnitude of current I_{cell} flowing through electrochemical cell assembly 106 is zero. However, one or more idle periods 1106 could be omitted such that a discharging interval 1104 immediately follows a charging interval 1102.

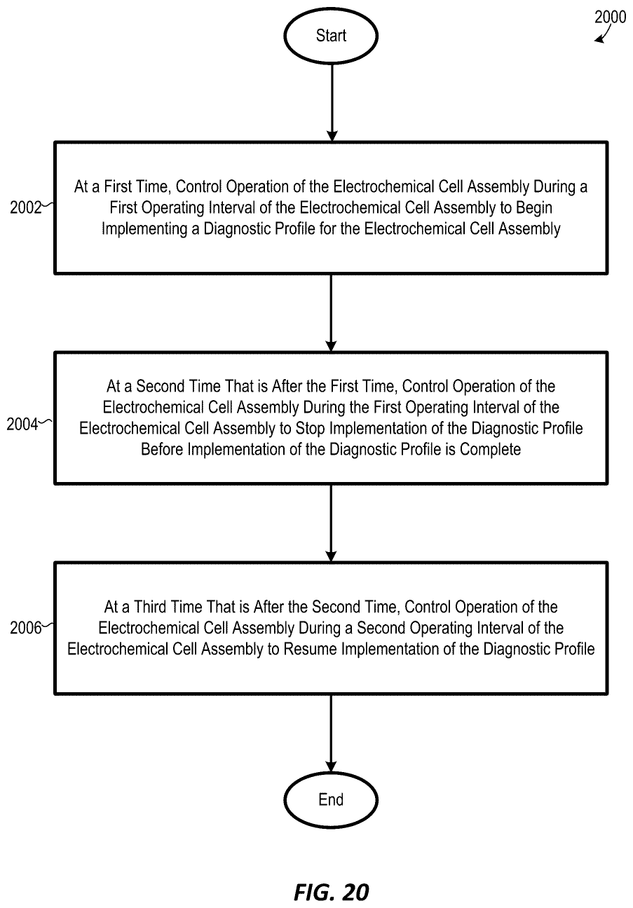

Controller 104 implements diagnostic profile segments 802(1), 802(2), and 802(3) in charging intervals 1102(1), 1102(2), and 1102(4), respectively. As such, implementation of diagnostic profile segment 802(2) is separated in time from implementation of diagnostic profile segment 802(1) by discharging interval 1104(1) and idle periods 1106(1) and 1106(2). Additionally, implementation of diagnostic profile segment 802(3) is separated in time from implementation of diagnostic profile segment 802(2) by discharging intervals 1104(2) and 1104(3), intervening charging interval 1102(3), and idle periods 1106(3)-1106(8). Times t₁, t₂, and t₃ shown in FIG. 11 are discussed below with respect to FIG. 20.

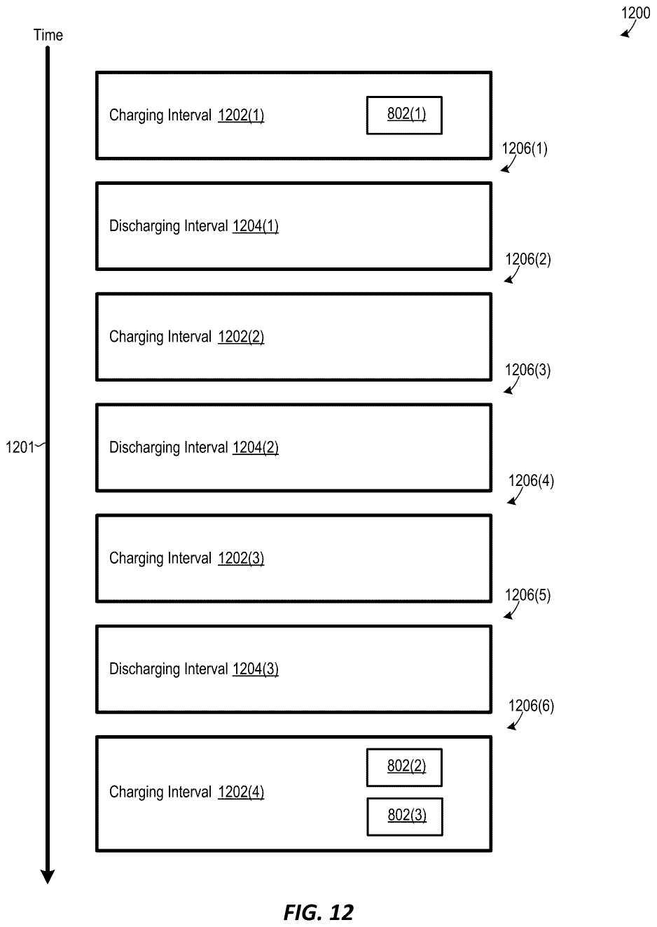

FIG. 12 is a timing diagram 1200 illustrating another example of controller 104 implementing diagnostic profile segments 802 over a plurality of charging intervals of electrochemical cell assembly 106. Increasing time is shown by an arrow 1201 in FIG. 12, and FIG. 12 illustrates alternating charging internals 1202 and discharging intervals 1204 of electrochemical cell assembly 106. FIG. 12 illustrates each charging interval 1202 being separated in time from a subsequent discharging interval 1204 by an idle period 1206 of electrochemical cell assembly 106 where magnitude of current I_{cell} flowing through electrochemical cell assembly 106 is zero. However, one or more idle periods 1206 could be omitted such that a discharging interval 1204 immediately follows a charging interval 1202.

Controller 104 implements diagnostic profile segment 802(1) in charging interval 1202(1), and controller 104 implements each of diagnostic profile segments 802(2) and 802(3) in a common charging interval 1202(4). As such, implementation of diagnostic profile segment 802(2) is separated in time from implementation of diagnostic profile segment 802(1) by discharging intervals 1204(1), 1204(2), and 1204(3), intervening charging intervals 1202(2) and 1202(3), and idle periods 1206(1)-1206(6). Diagnostic profile segment 802(3) is implemented relatively soon after implementation of diagnostic profile segment 802(2) in the FIG. 12 example. In some embodiments, electrochemical cell assembly 106 operates normally, e.g. according to a normal charging profile, between implementation of diagnostic profile segments 802(2) and 802(3) in charging interval 1202(4). In some other embodiments, electrochemical cell assembly 106 operates in an idle mode between implementation of diagnostic profile segments 802(2) and 802(3) in charging interval 1202(4).

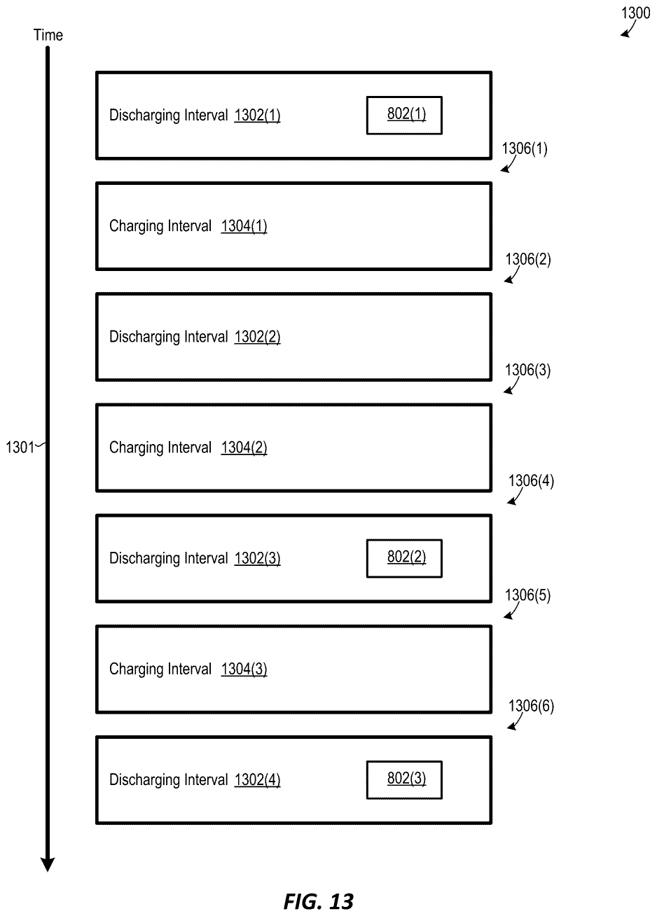

FIG. 13 is a timing diagram 1300 illustrating one example of controller 104 implementing diagnostic profile segments 802 over a plurality of discharging intervals of electrochemical cell assembly 106. Increasing time is shown by an arrow 1301 in FIG. 13, and FIG. 13 illustrates alternating discharging internals 1302 and charging intervals 1304 of electrochemical cell assembly 106. FIG. 13 illustrates each discharging interval 1302 being separated in time from a subsequent charging interval 1304 by an idle period 1306 of electrochemical cell assembly 106 where magnitude of current I_{cell} flowing through electrochemical cell assembly 106 is zero. However, one or more idle periods 1306 could be omitted such that a charging interval 1304 immediately follows a discharging interval 1302.

Controller 104 implements diagnostic profile segments 802(1), 802(2), and 802(3) in discharging intervals 1302(1), 1302(3), and 1302(4), respectively. As such, implementation of diagnostic profile segment 802(2) is separated in time from implementation of diagnostic profile segment 802(1) by charging intervals 1304(1) and 1304(2), intervening discharging interval 1302(2), and idle periods 1306(4)-1306(1). Additionally, implementation of diagnostic profile segment 802(3) is separated in time from implementation of diagnostic profile segment 802(2) by charging interval 1304(3) and idle periods 1306(5) and 1306(6).

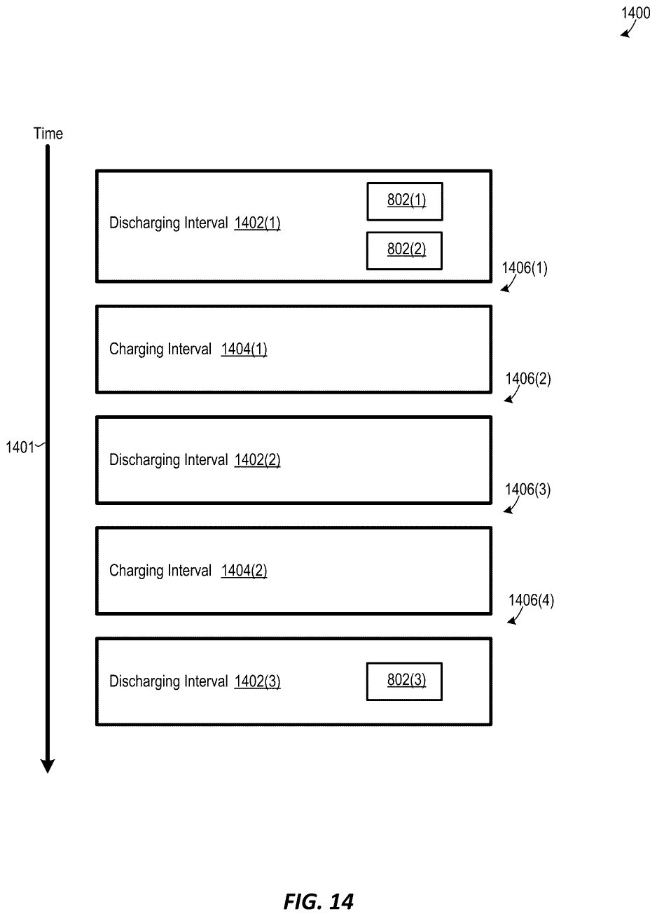

FIG. 14 is a timing diagram 1400 illustrating another example of controller 104 implementing diagnostic profile segments 802 over a plurality of discharging intervals of electrochemical cell assembly 106. Increasing time is shown by an arrow 1401 in FIG. 14, and FIG. 14 illustrates alternating discharging internals 1402 and charging intervals 1404 of electrochemical cell assembly 106. FIG. 14 illustrates each discharging interval 1402 being separated in time from a subsequent charging interval 1404 by an idle period 1406 of electrochemical cell assembly 106 where magnitude of current I_{cell} flowing through electrochemical cell assembly 106 is zero. However, one or more idle periods 1406 could be omitted such that a charging interval 1404 immediately follows a discharging interval 1402.

Controller 104 implements each of diagnostic profile segments 802(1) and 802(2) in discharging interval 1402(1), and controller 104 implements diagnostic profile segment 802(3) in discharging interval 1402(4). As such, implementation of diagnostic profile segment 802(3) is separated in time from implementation of diagnostic profile segment 802(2) by charging intervals 1404(1) and 1404(2), intervening discharging interval 1402(2), and idle periods 1406(1)-1406(4). Diagnostic profile segment 802(2) is implemented relatively soon after implementation of diagnostic profile segment 802(1) in the FIG. 14 example. In some embodiments, electrochemical cell assembly 106 operates normally, e.g. according to a normal discharging profile, between implementation of diagnostic profile segments 802(1) and 802(2) in discharging interval 1402(1). In some other embodiments, electrochemical cell assembly 106 operates in an idle mode between implementation of diagnostic profile segments 802(1) and 802(2) in discharging interval 1402(1).

Referring again to FIG. 6, in some embodiments, implementation instructions 614 are configured such that processing subsystem 602 may stop implementation of a diagnostic profile segment before implementation of the diagnostic profile segment is complete, such as in response to a signal indicating that electrochemical cell assembly 106 must immediately return to normal operation. In these embodiments, implementation instructions 614 may be configured so that controller 104 subsequently resumes implementation of the diagnostic profile segment at a place in the diagnostic profile segment where implementation of the diagnostic profile segment was stopped. Alternately, in these embodiments, implementation instructions 614 may be configured so that controller 104 subsequently resumes implementation of the diagnostic profile segment at the beginning of the diagnostic profile segment, instead of at the place in the diagnostic profile segment where implementation of the diagnostic profile segment was stopped.

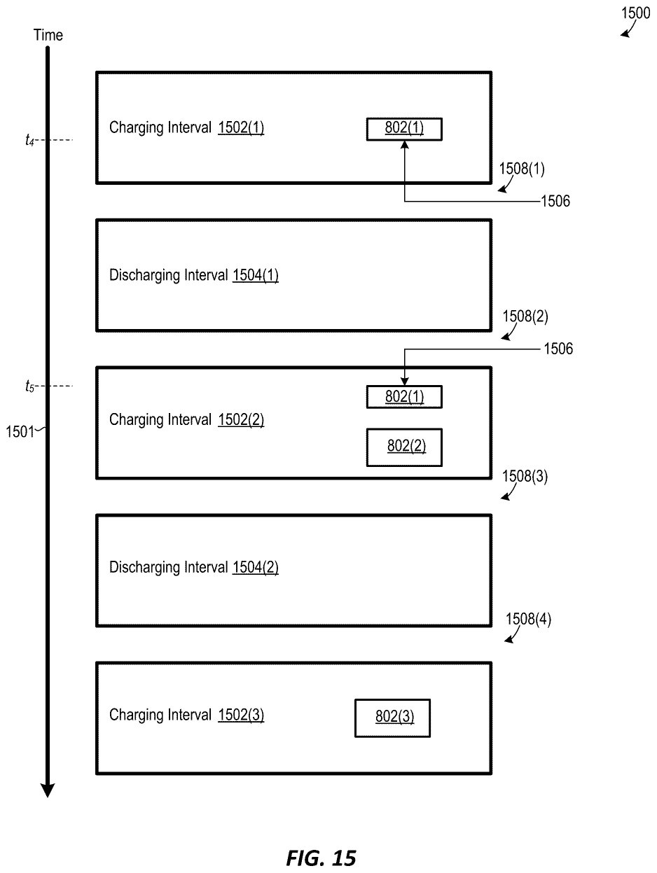

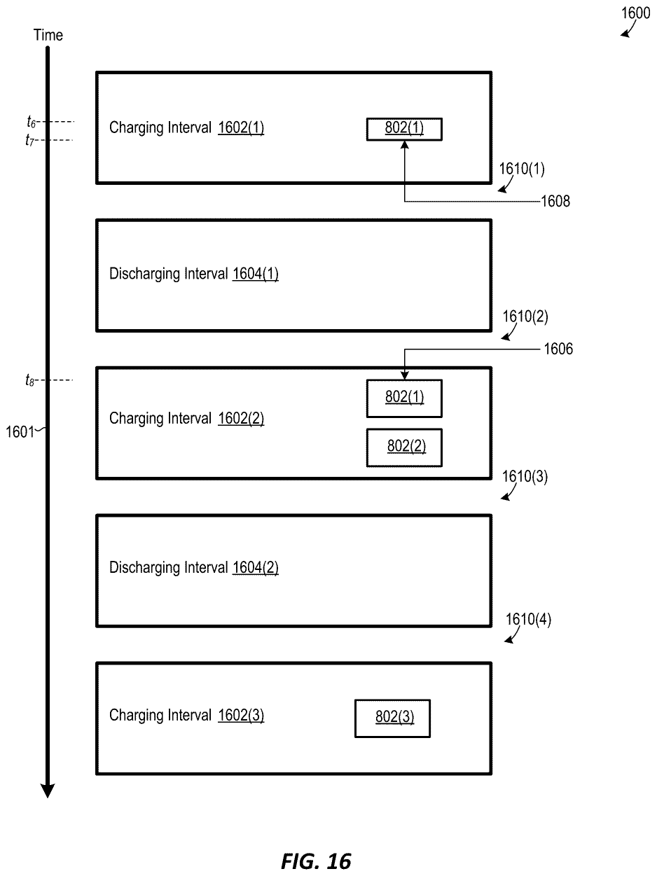

FIGS. 15 and 16 illustrate two respective examples where implementation of a diagnostic profile segment is stopped before the implementation of the diagnostic profile segment is complete. The examples of FIGS. 15 and 16 assume that (i) complete diagnostic profile 620 of FIG. 6 is embodied by complete diagnostic profile 700 of FIG. 7, (ii) complete diagnostic profile 700 is divided into diagnostic profile segments 802 of FIG. 8, and (iii) diagnostic profile segments 802 are implemented during charging of electrochemical cell assembly 106. It is understood, though, that the examples of FIGS. 15 and 16 could be adapted to other embodiments of complete diagnostic profile 620 as well as other divisions of complete diagnostic profile 620 into diagnostic profile segments. Additionally, the examples of FIGS. 15 and 16 could be adapted so that the diagnostic profile segments are implemented over discharging intervals of electrochemical cell assembly 106 instead of over charging intervals of electrochemical cell assembly 106.

FIG. 15 is a timing diagram 1500 illustrating one example of controller 104 implementing diagnostic profile segments 802 over a plurality of charging intervals of electrochemical cell assembly 106 where implementation of a diagnostic profile segment is stopped before its implementation is complete. Increasing time is shown by an arrow 1501 in FIG. 15, and FIG. 15 illustrates alternating charging internals 1502 and discharging intervals 1504 of electrochemical cell assembly 106. FIG. 15 illustrates each charging interval 1502 being separated in time from a subsequent discharging interval 1504 by an idle period 1508 of electrochemical cell assembly 106 where magnitude of current I_{cell} flowing through electrochemical cell assembly 106 is zero. However, one or more idle periods 1508 could be omitted such that a discharging interval 1504 immediately follows a charging interval 1502.

Controller 104 begins to implement diagnostic profile segment 802(1) in charging interval 1502(1), but controller 104 stops implementing diagnostic profile segment 802(1) at a time t₄ before implementation of diagnostic profile segment 802(1) is complete. Controller 104 resumes implementation of diagnostic profile segment 802(1) in charging interval 1502(2) at a time t₅ at a place 1506 in diagnostic profile segment 802(1) where implementation was stopped at time t₄. Controller 104 subsequently implements diagnostic profile segment 802(2) in charging interval 1502(2), and controller 104 implements diagnostic profile segment 802(3) in charging interval 1502(3).

FIG. 16 is a timing diagram 1600 illustrating another example of controller 104 implementing diagnostic profile segments 802 over a plurality of charging intervals of electrochemical cell assembly 106 where implementation of a diagnostic profile segment is stopped before its implementation is complete. Increasing time is shown by an arrow 1601 in FIG. 16, and FIG. 16 illustrates alternating charging internals 1602 and discharging intervals 1604 of electrochemical cell assembly 106. FIG. 16 illustrates each charging interval 1602 being separated in time from a subsequent discharging interval 1604 by an idle period 1610 of electrochemical cell assembly 106 where magnitude of current I_{cell} flowing through electrochemical cell assembly 106 is zero. However, one or more idle periods 1610 could be omitted such that a discharging interval 1604 immediately follows a charging interval 1602.

Controller 104 begins to implement diagnostic profile segment 802(1) in charging interval 1602(1), but controller 104 interrupts diagnostic profile segment 802(1) at a time t₇ before implementation of diagnostic profile segment 802(1) is complete. Controller 104 resumes implementation of diagnostic profile segment 802(1) in charging interval 1602(2) at a time t₈ at a beginning 1606 of diagnostic profile segment 802(1), instead of at a place 1608 in diagnostic profile segment 802(1) where implementation was stopped at time t₇. Controller 104 subsequently implements diagnostic profile segment 802(2) in charging interval 1602(2), and controller 104 implements diagnostic profile segment 802(3) in charging interval 1602(3). Time t₆, shown in FIG. 16, is discussed below with respect to FIG. 20.

Referring again to FIG. 6, processing subsystem 602 is configured to execute measurement instructions 616 to obtain measurement characteristics 624 of electrochemical cell assembly 106 during implementation of each of the plurality of diagnostic profile segments. Measurement characteristics 624 include, for example, raw data representing electrochemical cell assembly 106 during implementation of the plurality diagnostic profile segments and/or processed data representing electrochemical cell assembly 106 during implementation of the plurality of diagnostic profile segments. Examples of raw data include measurements of current I_{cell}, voltage V_{cell}, and/or temperature T_{cell} of electrochemical cell assembly 106 during implementation of the diagnostic profile segments. Such raw data is obtained by controller 104 from BMS node 102, for example, via feedback signals f. Examples of processed data include characteristics of electrochemical cell assembly 106 generated from raw data, e.g., impedance of electrochemical cell assembly 106 calculated from voltage V_{cell} and current I_{cell}.

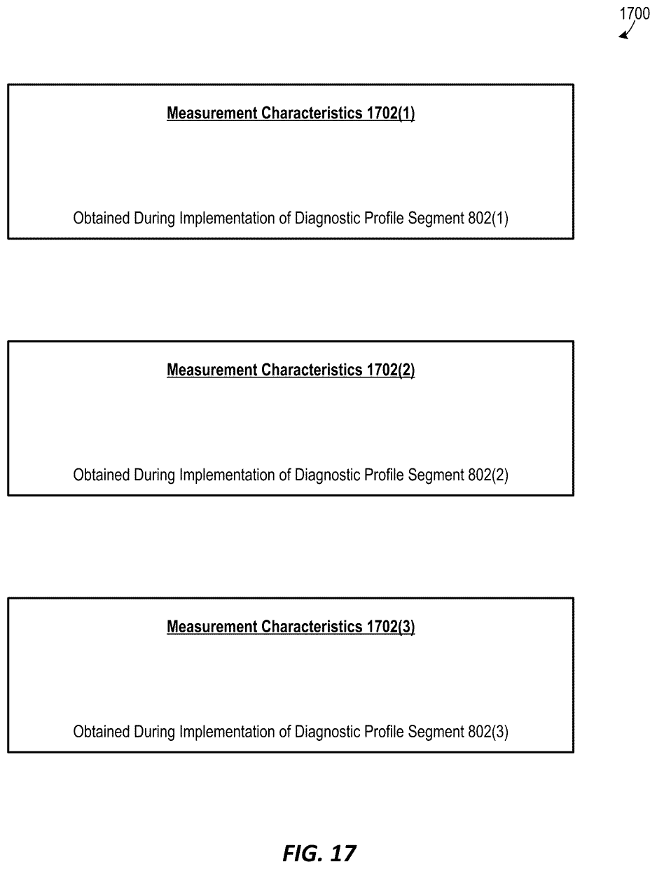

FIG. 17 illustrates a set of 1700 measurement characteristics 1702, where measurement characteristics 1702 are one example embodiment of measurement characteristics 624 in an embodiment where set 622 of diagnostic profile segments is embodied by set 800 of FIG. 8. Set 1700 includes measurement characteristics 1702(1), 1702(2), and 1702(3) obtained during implementation of diagnostic profile segments 802(1), 802(2), and 802(3), respectively. Each measurement characteristic 1702 includes raw data and/or processed data representing electrochemical cell assembly 106 during implementation of its respective diagnostic profile segment. For example, in some embodiments, (i) measurement characteristics 1702(1) include measurements of voltage V_{cell}, current I_{cell}, and/or temperature T_{cell} obtained at a plurality of different respective times during implementation of diagnostic profile segment 802(1), (ii) measurement characteristics 1702(2) include measurements of voltage V_{cell}, current I_{cell}, and/or temperature T_{cell} obtained at a plurality of different respective times during implementation of diagnostic profile segment 802(2), and (iii) measurement characteristics 1702(3) include measurements of voltage V_{cell}, current I_{cell}, and/or temperature T_{cell} obtained at a plurality of different respective times during implementation of diagnostic profile segment 802(3). Accordingly, in certain embodiments, each instance of measurement characteristics 1702 includes a large amount of data.

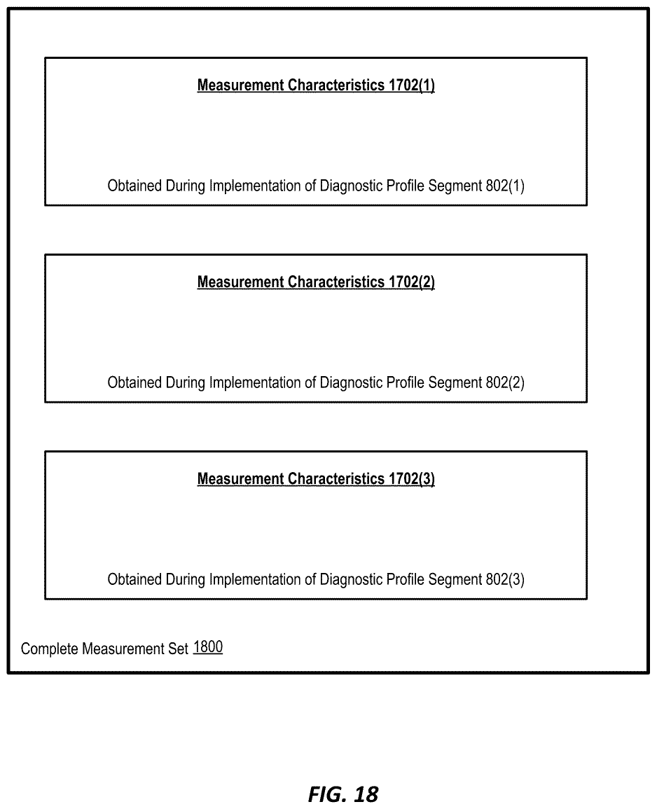

Referring again to FIG. 6, processing subsystem 602 is configured to execute combining instructions 618 to combine each measurement characteristic 624 into a complete measurement set 626. As such, complete measurement set 626 represents characteristics of electrochemical cell assembly 106 over complete diagnostic profile 620. FIG. 18 illustrates a complete measurement set 1800, where complete measurement set 1800 is one example embodiment of complete measurement set 626 in an embodiment where measurement characteristics 624 are embodied by measurement characteristics 1702 of FIG. 17. As shown in FIG. 18, complete measurement set 1800 includes each instance of measurement characteristics 1702, such that complete measurement set 1800 represents one or more characteristics of electrochemical cell assembly, e.g., voltage V_{cell}, current I_{cell}, temperature T_{cell}, and/or one or more parameters derived therefrom, over complete diagnostic profile 620. Complete measurement set 1800 is optionally analyzed by controller 104, and/or one or more other elements (not shown), to determine SOH, SOD, and/or SOS of electrochemical cell assembly 106 using techniques known in the art of electrochemical cell diagnostics.

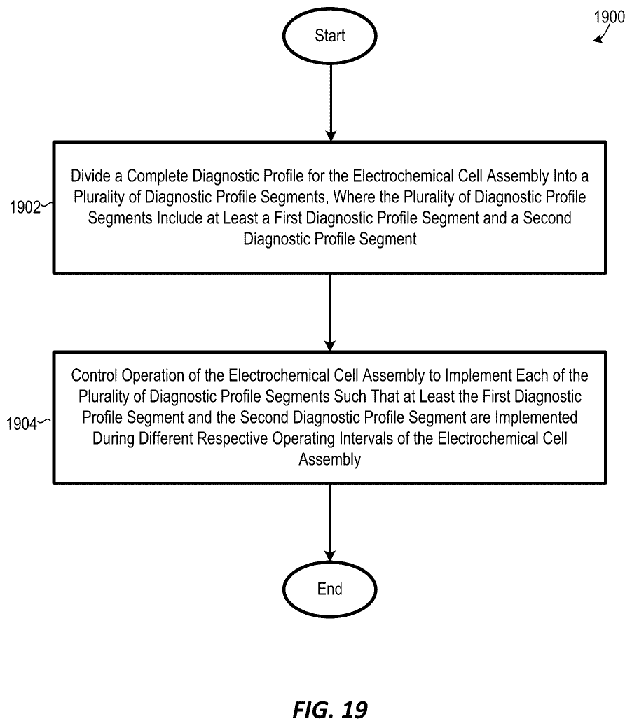

FIGS. 19 and 20 collectively illustrate two additional examples of operation of controller 104. It is understood, though, controller 104 is not limited to operating according to the examples of FIGS. 19 and 20.

FIG. 19 is a flow chart of a method 1900 for implementing a diagnostic profile for an electrochemical cell assembly. In a block 1902 of method 1900, a complete diagnostic profile for an electrochemical cell assembly is divided into a plurality of diagnostic profile segments, where the plurality of diagnostic profile segments includes at least a first diagnostic profile segment and a second diagnostic profile segment. In one example of block 1902, processing subsystem 602 executes dividing instructions 612 to divide complete diagnostic profile 700 (FIG. 7) into diagnostic profile segments 802 (FIG. 8). In a block 1904 of method 1900, operation of the electrochemical cell assembly is controlled to implement each of the plurality of diagnostic profile segments such that at least the first diagnostic profile segment and the second diagnostic profile segment are implemented during different respective operating intervals of the electrochemical cell assembly. In one example of block 1904, processing subsystem 602 executes implementation instructions 614 to implement diagnostic profile segments 802 according to the timing diagram of any one of FIGS. 11-16.

FIG. 20 is a flow chart of a method for implementing a diagnostic profile for an electrochemical cell assembly. In a block 2002 of method 2000, at a first time, operation of the electrochemical cell assembly is controlled during a first operating interval of the electrochemical cell assembly to begin implementing a diagnostic profile for the electrochemical cell assembly. In one example of block 2002, processing subsystem 602 executes implementation instructions 614 to begin implementing diagnostic profile segment 802(1) of complete diagnostic profile 700 at a time t₁, as illustrated in FIG. 11. As another example of block 2002, processing subsystem 602 executes implementation instructions 614 to begin implementing diagnostic profile segment 802(1) of complete diagnostic profile 700 at a time t₆, as illustrated in FIG. 16.

In a block 2004 of method 2000, at a second time that is after the first time, operation of the electrochemical cell assembly is controlled during the first operating interval of the electrochemical cell assembly to stop implementation of the diagnostic profile before implementation of the diagnostic profile is complete. In one example of block 2004, processing subsystem 602 executes implementation instructions 614 to stop implementing complete diagnostic profile 700 after completion of diagnostic profile segment 802(1) at a time t₂, as illustrated in FIG. 11. In another example of block 2004, processing subsystem 602 executes implementation instructions 614 to stop implementing complete diagnostic profile 700 at a time t₇ before implementation of diagnostic profile segment 802(1) is complete, as illustrated in FIG. 16.

In a block 2006 of method 2000, at a third time that is after the second time, operation of the electrochemical cell assembly is controlled during a second operating interval of the electrochemical cell assembly to resume implementation of the diagnostic profile. In one example of block 2006, processing subsystem 602 executes implementation instructions 614 to resume implementing complete diagnostic profile 700 by beginning to implement diagnostic profile segment 802(2) at a time t₃, as illustrated in FIG. 11. In another example of block 2006, processing subsystem 602 executes implementation instructions 614 to resume implementing complete diagnostic profile 700 by again beginning to implement diagnostic profile segment 802(1) at a time t₈, as illustrated in FIG. 16.

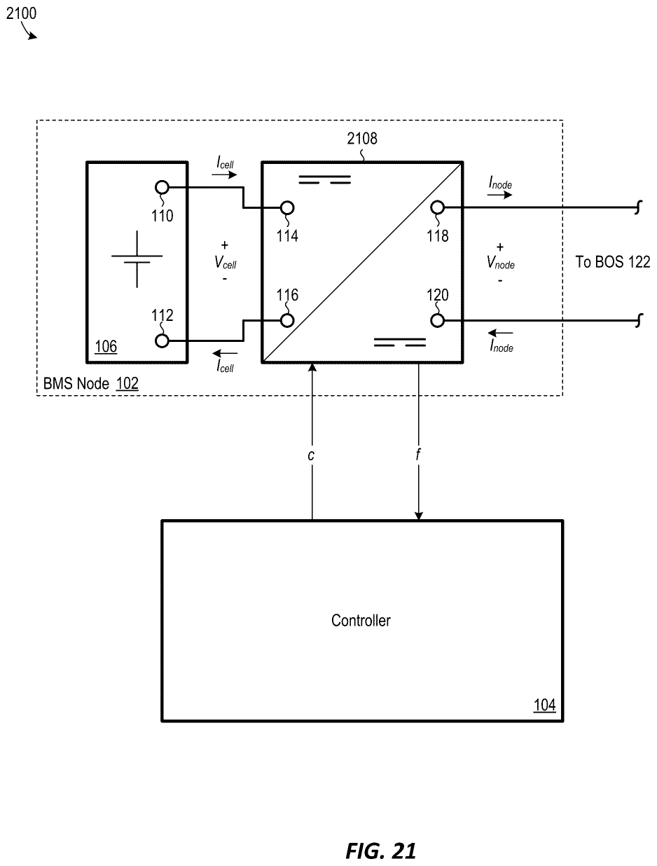

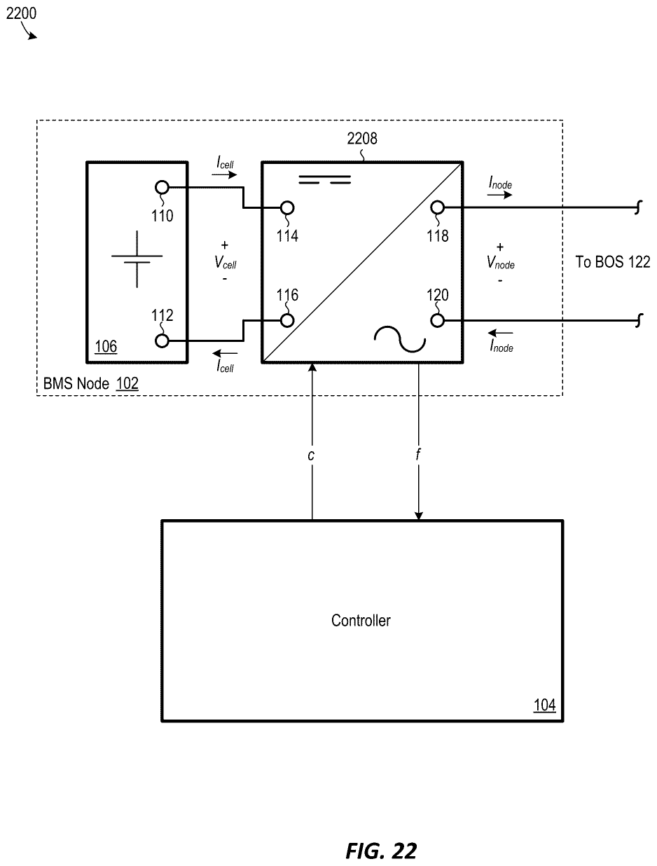

Referring again to FIG. 1, as discussed above, in certain embodiments, power converter 108 is a DC-to-DC converter or an inverter. For example, FIG. 21 is a schematic diagram of an electrical environment 2100, which is an embodiment of electrical environment 100 where power converter 108 is embodied by a DC-to-DC converter 2108. As another example, FIG. 22 is a schematic diagram of an electrical environment 2200, which is an embodiment of electrical environment 100 where power converter 108 is embodied by an inverter 2208.

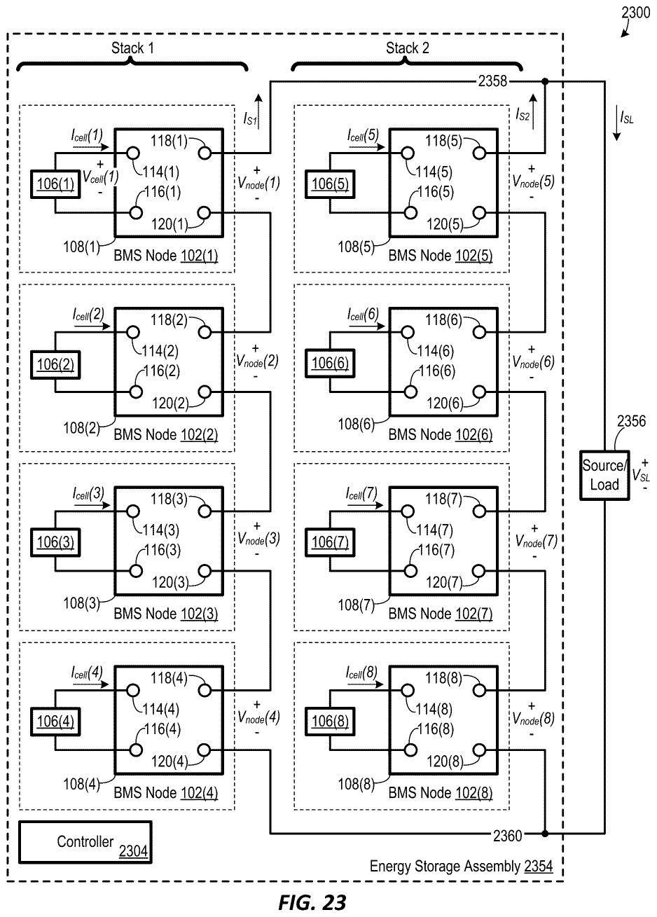

Referring again to FIG. 1, controller 104 is optionally configured to control one or more BMS nodes (not shown) in addition to BMS node 102. For example, FIG. 23 is a schematic diagram of an electrical environment 2300 including an energy storage assembly 2354 and a source/load 2356. Energy storage assembly 2354 includes a plurality of BMS nodes 102 and a controller 2304. Some elements of BMS nodes 102, e.g., positive cell assembly ports 110 and negative cell assembly ports 112, are not shown in FIG. 23 for illustrative clarity. BMS nodes 102 are arranged into two stacks, i.e., a Stack 1 and a Stack 2, in energy storage assembly 2354. Stack 1 includes BMS nodes 102(1)-102(4), and Stack 2 includes BMS nodes 102(5)-102(8). The quantity of BMS nodes 102 in each stack may vary, and each stack need not include the same quantity of BMS nodes 102. Additionally, the quantity of stacks in energy storage assembly 2354 may vary. For example, in one alternate embodiment, energy storage assembly 2354 includes solely Stack 1, i.e., Stack 2 is omitted. As another example, in another alternate embodiment, energy storage assembly 2354 includes one or more stacks in addition to Stack 1 and Stack 2.

BMS nodes 102 within a given stack are electrically coupled in series via positive output ports 118 and negative output ports 120 between a first power bus 2358 and a second power bus 2360. For example, BMS node 102(1) is electrically coupled in series with first power bus 2358 via positive output port 118(1), and BMS node 102(1) is electrically coupled in series with BMS node 102(2) via negative output port 120(1). As another example, BMS node 102(2) is electrically coupled in series with BMS node 102(1) via positive output port 118(2), and BMS node 102(2) is electrically coupled in series with BMS node 102(3) via negative output port 120(2). Voltages V_{node} across positive output ports 118 and negative output ports 120 of BMS nodes 102 may vary among BMS nodes 102. However, current through positive output ports 118 and negative output ports 120 is the same for all BMS nodes 102 within a given stack. In particular, a current Iₛ₁ flows through all positive output ports 118 and negative output ports 120 in Stack 1, and a current Iₛ₂ flows through all positive output ports 118 and negative output ports 120 in Stack 2.

Stack 1 and Stack 2 are electrically coupled in parallel with source/load 2356 via first power bus 2358 and second power bus 2360. Stack 1 and Stack 2 collectively provide a current I_{SL} and a voltage V_{SL} to source/load 2356. Source/load 2356 provides electric power to energy storage assembly 2354 when source/load 2356 operates as an electric power source, and source/load 2356 consumes electric power from energy storage assembly 2354 when source/load 2356 operates as a load. Although source/load 2356 is symbolically shown as a single element, source/load 2356 could include a plurality of elements, such as a source and a load, a plurality of sources, and/or a plurality of loads. Additionally, source/load 2356 may include interface devices, such as DC-to-AC converters, DC-to-DC converters, and/or transformers, configured to electrically couple energy storage assembly 2354 with an energy source and/or an energy sink. In some embodiments, source/load 2356 includes one or more of an alternating current (AC) electric power system (e.g., an AC electric power grid), a DC electric power system, an electromechanical device, and a photovoltaic device, which are optionally electrically coupled to energy storage assembly 2354 via a DC-to-AC converter of source/load 2356, a DC-to-DC converter of source/load 2356, and/or a transformer of source/load 2356. However, source/load 2356 can take other forms without departing from the scope hereof.

Controller 2304 is an alternate embodiment of controller 104 (FIG. 1) which is configured to implement a respective diagnostic profile for each electrochemical cell assembly 106 by controlling a respective power converter 108 electrically coupled to the electrochemical cell assembly 106. Additionally, controller 2304 is configured to control each control power converter 108 such that the respective diagnostic profile for each electrochemical cell assembly 106 may be divided into a plurality of diagnostic profile segments that are implemented over two or more different operating intervals of the electrochemical cell assembly 106, in a manner analogous to that discussed above with respect to controller 104. Certain embodiments of controller 2304 are also configured to obtain measurement characteristics during implementation of each diagnostic profile segment on a given electrochemical cell assembly 106 and combine the obtained measurement characteristics to generate a complete measurement set for the electrochemical cell assembly 106, in a manner analogous to that discussed above with respect to controller 104. In some embodiments, controller 2304 is configured to cause a given electrochemical cell assembly 106 to operate in an idle mode between implementation of successive diagnostic profile segments within a common charging or discharging interval. In some other embodiments, controller 2304 is configured to cause a given electrochemical cell assembly 106 to operate normally, e.g., in the same manner as electrochemical cell assemblies 106 that are not undergoing a diagnostic profile implementation, between implementation of successive diagnostic profile segments within a common charging or discharging interval.

While not required, it is anticipated that controller 2304 will typically be configured to implement respective diagnostic profiles on only a subset of electrochemical cell assemblies 106 at any given time to minimize interfering with normal operation of energy storage assembly 2354. For example, controller 2304 may be configured to implement a diagnostic profile on one electrochemical cell assembly 106 at a time, such as according to a predetermined schedule, e.g., periodically, or on demand, such as in response to a signal indicating a possible anomaly with the electrochemical cell assembly 106. As another example, controller 2304 may be configured to implement a diagnostic profile on one group of electrochemical cell assemblies 106 at a time, such as according to a predetermined schedule, e.g., periodically. As a further example, controller 2304 may be configured to implement a diagnostic profile, and/or a given diagnostic profile segment of a diagnostic profile, on an electrochemical cell assembly 106 in response to one or more criteria being met, such as one or more of (i) state of charge of the electrochemical cell assembly 106 crossing a predetermined threshold value or being within a predetermined state of charge range, (ii) voltage V_{cell} across the electrochemical cell assembly 106 crossing a predetermined threshold value or being within a predetermined voltage range, (iii) magnitude of current I_{cell} flowing through the electrochemical cell assembly 106 crossing a predetermined threshold value or being within a predetermined current range, (iv) temperature of the electrochemical cell assembly 106 crossing a threshold value or being with a predetermined temperature range, (v) magnitude of power of the electrochemical cell assembly 106, which is equal to the product of V_{cell} and I_{cell}, crossing a threshold value or being within a predetermined power range, etc. Although controller 2304 is depicted as a single element, controller 2304 may include multiple constituent sub-elements which need not be co-located. Additionally, controller 2304 could be partially or fully combined with one or more other elements.

In certain embodiments, controller 2304 is configured to control power converters 108 to implement a diagnostic profile on one or more electrochemical cell assemblies when energy storage assembly 2354 is operating in a standby mode, i.e., when energy storage assembly 2354 neither provides power to source/load 2356 nor receives power from source/load 2356. Certain embodiments of controller 2304 are configured to control power converters 108 under such conditions such that one or more electrochemical cell assemblies 106 of energy storage assembly 2354 may serve as a load or power source for one or more other electrochemical cell assemblies 106 of energy storage assembly 2354, when implementing diagnostic profiles on one or more electrochemical cell assemblies 106. For example, assume that power converter 108(1) needs to provide charging current pulses to electrochemical cell assembly 106(1) to implement a diagnostic profile segment for electrochemical cell assembly 106(1). Controller 2304 may control one or more other electrochemical cell assemblies 106 via their respective power converters 108 to provide energy needed for charging current pulses applied to electrochemical cell assembly 106(1).

Certain embodiments of controller 2304 are configured to control power converters 108 such that each electrochemical cell assembly 106 may operate under its own respective operating conditions, or stated differently, such that operating conditions may vary among electrochemical cell assemblies 106 in energy storage assembly 2354. While not required, operating conditions of electrochemical cell assemblies 106 in energy storage assembly 2354 will typically vary among electrochemical cell assemblies 106 according to whether the electrochemical cell assemblies 106 are undergoing a diagnostic profile implementation. For example, a charge or discharge rate of an electrochemical cell assembly undergoing a diagnostic profile implementation may be different from a charge or discharge rate of an electrochemical cell assembly 106 that is operating normally, i.e., not undergoing a diagnostic profile implementation. As another example, charge or discharge rates of all electrochemical cell assemblies 106 may be the same, but duration of charging or discharging may differ among electrochemical cell assemblies 106 according to whether the electrochemical cell assemblies 106 are undergoing a diagnostic profile implementation. As an additional example, charge or discharge rate, as well as charge or discharge duration, may vary among electrochemical cell assemblies 106 according to whether the electrochemical cell assemblies 106 are undergoing a diagnostic profile implementation.

Implementing a diagnostic profile on an electrochemical cell assembly 106 may change an operating power of energy storage assembly 2354, i.e., it may change amount of power provided by energy storage assembly 2354 to source/load 2356 or it may change the amount of power received by energy storage assembly 2354 from source/load 2356. Such change in operating power of energy storage assembly 2354 may be undesirable, e.g., because it interferes with normal operation of energy storage assembly 2354. Accordingly, certain embodiments of controller 2304 are configured to control one or more power converters 108 to compensate for change in operation of an electrochemical cell assembly 106 resulting from implementing a diagnostic profile on the electrochemical cell assembly 106, thereby preventing implementation of a diagnostic profile on an electrochemical cell assembly 106 from changing an operating power of energy storage assembly 2354.

For example, assume that (a) controller 2304 controls power converter 108(1) to cause electrochemical cell assembly 106(1) to change its operation by operating at a constant magnitude of current I_{cell}(1) as part of implementing a diagnostic profile segment on electrochemical cell assembly 106(1) and (b) such change in operation of electrochemical cell assembly 106(1) causes magnitude of its power provided to source/load 2356, or magnitude of its power received from source/load 2356, to change by Δp₁(t). Δp₁(t) could be either positive or negative, and Δp₁(t) is a function of time because power provided by electrochemical cell assembly 106(1), or power received by electrochemical cell assembly 106(1), will vary with time as voltage V_{cell}(1) changes. Controller 2304 may change operation of one or more other electrochemical cell assemblies 106(2)-106(8) to compensate for the change in operation of electrochemical cell assembly 106(1) and thereby prevent change in operating power of energy storage assembly 2354. For example, controller 2304 may control power converter 108(2) to cause electrochemical cell assembly 106(2) to change its power provided, or its power received, by −Δp₁(t), thereby offsetting the change in power of Δp₁(t) of electrochemical cell assembly 106(1). As another example, controller 2304 may control power converters 108(2) and 108(3) to respectively cause electrochemical cell assemblies 106(2) and 106(3) to change their respective powers provided, or their respective powers received, by −Δp₁(t)/2, thereby offsetting the change in power of Δp₁(t) of electrochemical cell assembly 106(1).

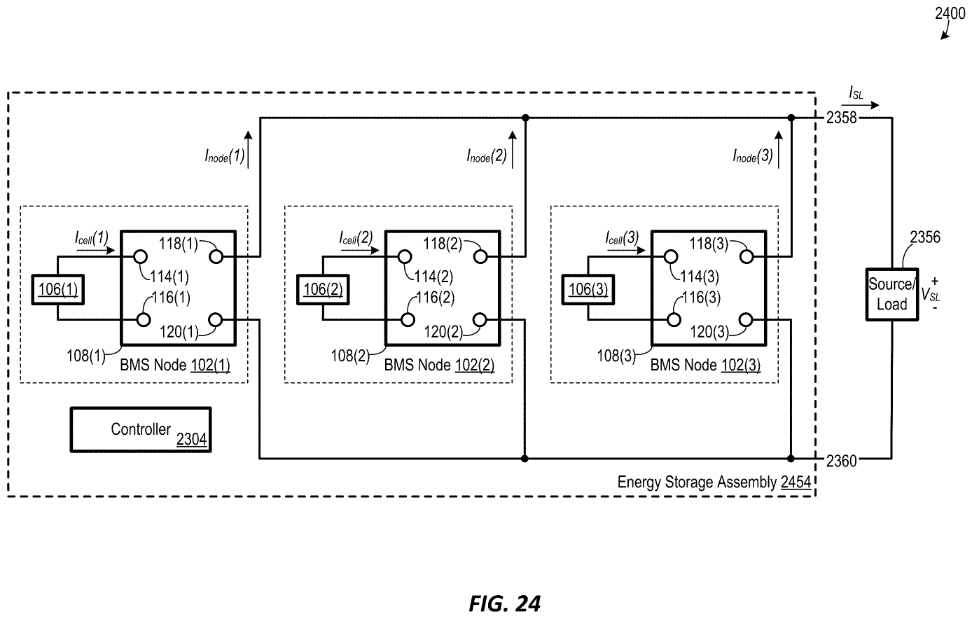

FIG. 24 is a schematic diagram of an electrical environment 2400, which is an alternate embodiment of electrical environment 2300 (FIG. 23) where energy storage assembly 2354 is replaced with an energy storage assembly 2454. Energy storage assembly 2454 differs from energy storage assembly 2354 in that energy storage assembly 2454 includes a plurality of BMS nodes 102 electrically coupled in parallel via first power bus 2358 and second power bus 2360, instead of stacks of BMS nodes 102 electrically coupled in series. BMS nodes 102 will have a common voltage V_{SL} across their positive output ports 118 and negative output ports 120. However, each BMS node 102 will have a respective current I_{node} flowing through its positive output port 118 and its negative output port 120, where currents I_{node} sum to current I_{SL} flowing through source/load 2356. Energy storage assembly 2454 operates in a manner similar to energy storage assembly 2354. For example, controller 2304 is configured to implement a respective diagnostic profile for each electrochemical cell assembly 106 by (i) dividing a complete diagnostic profile segment for the electrochemical cell assembly 106 into a plurality of diagnostic profile segments and (ii) controlling a respective power converter 108 of the electrochemical cell assembly 106 to implement at least two of the plurality of diagnostic profile segments over two or more different operating intervals of the electrochemical cell assembly 106. As another example, certain embodiments of controller 2304 are also configured to obtain measurement characteristics during implementation of each diagnostic profile segment on a given electrochemical cell assembly 106 and combine the obtained measurement characteristics to generate a complete measurement set for the electrochemical cell assembly 106, in a manner analogous to that discussed above with respect to controller 104.

### Combinations of Features

Features described above may be combined in various ways without departing from the scope hereof. The following examples illustrate some possible combinations.

(A1) A method for implementing a diagnostic profile for an electrochemical cell assembly includes (1) dividing a complete diagnostic profile for the electrochemical cell assembly into a plurality of diagnostic profile segments, the plurality of diagnostic profile segments including at least a first diagnostic profile segment and a second diagnostic profile segment and (2) controlling operation of the electrochemical cell assembly to implement each of the plurality of diagnostic profile segments such that at least the first diagnostic profile segment and the second diagnostic profile segment are implemented during different respective operating intervals of the electrochemical cell assembly.

(A2) In the method denoted as (A1), (1) the different respective operating intervals of the electrochemical cell assembly may include a first charging interval of the electrochemical cell assembly and a second charging interval of the electrochemical cell assembly and (2) the second charging interval of the electrochemical cell assembly may be separated in time from the first charging interval of the electrochemical cell assembly by at least one of (i) a discharging interval of the electrochemical cell assembly and (ii) an idle period of the electrochemical cell assembly.

(A3) In the method denoted as (A2), the second charging interval of the electrochemical cell assembly may be further separated in time from the first charging interval of the electrochemical cell assembly by at least one intervening charging interval of the electrochemical cell assembly.

(A4) In the method denoted as (A1), (1) the different respective operating intervals of the electrochemical cell assembly may include a first discharging interval of the electrochemical cell assembly and a second discharging interval of the electrochemical cell assembly and (2) the second discharging interval of the electrochemical cell assembly may be separated in time from the first discharging interval of the electrochemical cell assembly by at least one of (i) a charging interval of the electrochemical cell assembly and (ii) an idle period of the electrochemical cell assembly.

(A5) In the method denoted as (A4), the second discharging interval of the electrochemical cell assembly may be further separated in time from the first discharging interval of the electrochemical cell assembly by at least one intervening discharging interval of the electrochemical cell assembly.

(A6) Any one of the methods denoted as (A1) through (A5) may further include controlling operation of the electrochemical cell assembly to implement each diagnostic profile segment at a different respective state of charge range of the electrochemical cell assembly.

(A7) In any one of the methods denoted as (A1) through (A6), (1) controlling operation of the electrochemical cell assembly to implement the first diagnostic profile segment may include causing the electrochemical cell assembly to operate at a first predetermined diagnostic operating condition and (2) controlling operation of the electrochemical cell assembly to implement the second diagnostic profile segment may include causing the electrochemical cell assembly to operate at a second predetermined diagnostic operating condition.

(A8) In the method denoted as (A7), the second predetermined diagnostic operating condition may be different from the first predetermined diagnostic operating condition.

(A9) In the method denoted as (A7), the second predetermined diagnostic operating condition may be the same as the first predetermined diagnostic operating condition.

(A10) In any one of the methods denoted as (A7) through (A9), controlling operation of the electrochemical cell assembly to implement the first diagnostic profile segment may further include causing the electrochemical cell assembly to operate in a rest state after causing the electrochemical cell assembly to operate at the first predetermined diagnostic operating condition. (A11) In any one of the methods denoted as (A7) through (A10), (1) the first predetermined diagnostic operating condition may include one of a first rate of charge of the electrochemical cell assembly and a first rate of discharge of the electrochemical cell assembly and (2) the second predetermined diagnostic operating condition may include one of a second rate of charge of the electrochemical cell assembly and a second rate of discharge of the electrochemical cell assembly.

(A12) In any one of the methods denoted as (A7) through (A10), (1) the first predetermined diagnostic operating condition may include at least one of (i) a first operating current level of the electrochemical cell assembly and (ii) a first operating voltage level of the electrochemical cell assembly and (2) the second predetermined diagnostic operating condition may include at least one of (i) a second operating current level of the electrochemical cell assembly and (ii) a second operating voltage level of the electrochemical cell assembly.

(A13) In any one of the methods denoted as (A7) through (A10), (1) the first predetermined diagnostic operating condition may include a first operating power level of the electrochemical cell assembly and (2) the second predetermined diagnostic operating condition may include a second operating power level of the electrochemical cell assembly.

(A14) Any one of the methods denoted as (A1) through (A13) may further include (1) obtaining one or more measurement characteristics of the electrochemical cell assembly during implementation of each of the plurality of diagnostic profile segments and (2) combining the one or more measurement characteristics of the electrochemical cell assembly obtained during implementation of each of the plurality of diagnostic profile segments to generate a complete measurement set representing characteristics of the electrochemical cell assembly over the complete diagnostic profile.

(A15) In any one of the methods denoted as (A1) through (A14), controlling operation of the electrochemical cell assembly to implement each of the plurality of diagnostic profile segments such that at least the first diagnostic profile segment and the second diagnostic profile segment are implemented during different respective operating intervals of the electrochemical cell assembly may include controlling one or more power converters electrically coupled to the electrochemical cell assembly.

(A16) In the method denoted as (A15), the one or more power converters electrically coupled to the electrochemical cell assembly may include one or more of (i) an inverter and (ii) a direct-current-to-direct-current (DC-to-DC) converter.

(B1) A method for implementing a diagnostic profile for an electrochemical cell assembly includes (1) at a first time, controlling operation of the electrochemical cell assembly during a first operating interval of the electrochemical cell assembly to begin implementing a diagnostic profile for the electrochemical cell assembly, (2) at a second time that is after the first time, controlling operation of the electrochemical cell assembly during the first operating interval of the electrochemical cell assembly to stop implementation of the diagnostic profile before implementation of the diagnostic profile is complete, and (3) at a third time that is after the second time, controlling operation of the electrochemical cell assembly during a second operating interval of the electrochemical cell assembly to resume implementation of the diagnostic profile.

(B2) In the method denoted as (B1), controlling operation of the electrochemical cell assembly during the second operating interval of the electrochemical cell assembly to resume implementation of the diagnostic profile may include resuming implementation of the diagnostic profile at a same place in the diagnostic profile where implementation of the diagnostic profile was stopped at the second time.

(B3) In the method denoted as (B1), (1) the diagnostic profile may include a plurality of diagnostic profile segments and (2) controlling operation of the electrochemical cell assembly during the second operating interval of the electrochemical cell assembly to resume implementation of the diagnostic profile may include resuming implementation of the diagnostic profile at a beginning of a particular diagnostic profile segment of the plurality of diagnostic profile segments that was being implemented at the second time.

(B4) In any one of the methods denoted as (B1) through (B3), (1) the first operating interval of the electrochemical cell assembly may be a first charging interval of the electrochemical cell assembly, (2) the second operating interval of the electrochemical cell assembly may be a second charging interval of the electrochemical cell assembly, and (3) the second charging interval of the electrochemical cell may be separated in time from the first charging interval of the electrochemical cell assembly by at least one of (i) a discharging interval of the electrochemical cell assembly and (ii) an idle period of the electrochemical cell assembly.

(B5) In the method denoted as (B4), the second charging interval of the electrochemical cell assembly may be further separated in time from the first charging interval of the electrochemical cell assembly by at least one intervening charging interval of the electrochemical cell assembly.

(B6) In any one of the methods denoted as (B1) through (B3), (1) the first operating interval of the electrochemical cell assembly may be a first discharging interval of the electrochemical cell assembly, (2) the second operating interval of the electrochemical cell assembly may be a second discharging interval of the electrochemical cell assembly, and (3) the second discharging interval of the electrochemical cell assembly may be separated in time from the first discharging interval of the electrochemical cell assembly by at least one of (i) a charging interval of the electrochemical cell assembly and (ii) an idle period of the electrochemical cell assembly.

(B7) In the method denoted as (B6), the second discharging interval of the electrochemical cell assembly may be further separated in time from the first discharging interval of the electrochemical cell assembly by at least one intervening discharging interval of the electrochemical cell assembly

(B8) In any one of the methods denoted as (B1) through (B7), the diagnostic profile may include a plurality of predetermined diagnostic operating conditions of the electrochemical cell assembly corresponding to different respective state of charge ranges of the electrochemical cell assembly.

(B9) In any one of the methods denoted as (B1) through (B8), controlling operation of the electrochemical cell assembly during each of the first operating interval and the second operating interval may include controlling one or more power converters electrically coupled to the electrochemical cell assembly.

(B10) In the method denoted as (B9), the one or more power converters electrically coupled to the electrochemical cell assembly may include one or more of (i) an inverter and (ii) a direct-current-to-direct-current (DC-to-DC) converter.

(C1) A controller for implementing a diagnostic profile for an electrochemical cell assembly includes a storage subsystem and a processing subsystem communicatively coupled to each of the storage subsystem and one or more power converters. The one or more power converters are configured to control operation of the electrochemical cell assembly. The processing subsystem is configured to execute instructions stored in the storage subsystem to (1) divide a complete diagnostic profile for the electrochemical cell assembly into a plurality of diagnostic profile segments, the plurality of diagnostic profile segments including at least a first diagnostic profile segment and a second diagnostic profile segment and (2) control the one or more power converters to control operation of the electrochemical cell assembly to implement each of the plurality of diagnostic profile segments such that at least the first diagnostic profile segment and the second diagnostic profile segment are implemented during different respective operating intervals of the electrochemical cell assembly.

(C2) In the controller denoted as (C1), (1) the different respective operating intervals of the electrochemical cell assembly may include a first charging interval of the electrochemical cell assembly and a second charging interval of the electrochemical cell assembly and (2) the second charging interval of the electrochemical cell assembly may be separated in time from the first charging interval of the electrochemical cell assembly by at least one of (i) a discharging interval of the electrochemical cell assembly and (ii) an idle period of the electrochemical cell assembly.

(C3) In the controller denoted as (C2), the second charging interval of the electrochemical cell assembly may be further separated in time from the first charging interval of the electrochemical cell assembly by at least one intervening charging interval of the electrochemical cell assembly.

(C4) In the controller denoted as (C1), (1) the different respective operating intervals of the electrochemical cell assembly may include a first discharging interval of the electrochemical cell assembly and a second discharging interval of the electrochemical cell assembly and (2) the second discharging interval of the electrochemical cell assembly may be separated in time from the first discharging interval of the electrochemical cell assembly by at least one of (i) a charging interval of the electrochemical cell assembly and (ii) an idle period of the electrochemical cell assembly.

(C5) In the controller denoted as (C4), the second discharging interval of the electrochemical cell assembly may be further separated in time from the first discharging interval of the electrochemical cell assembly by at least one intervening discharging interval of the electrochemical cell assembly.

(C6) In any one of the controllers denoted as (C1) through (C5), the processing subsystem may be further configured to execute instructions stored in the storage subsystem to control operation of the electrochemical cell assembly to implement each diagnostic profile segment at a different respective state of charge range of the electrochemical cell assembly.

(C7) In any one of the controllers denoted as (C1) through (C6), (1) controlling operation of the electrochemical cell assembly to implement the first diagnostic profile segment may include controlling the one or more power converters to cause the electrochemical cell assembly to operate at a first predetermined diagnostic operating condition and (2) controlling operation of the electrochemical cell assembly to implement the second diagnostic profile segment may include controlling the one or more power converters to cause the electrochemical cell assembly to operate at a second predetermined diagnostic operating condition.

(C8) In the controller denoted as (C7), the second predetermined diagnostic operating condition may be different from the first predetermined diagnostic operating condition.

(C9) In controller denoted as (C7), the second predetermined diagnostic operating condition may be the same as the first predetermined diagnostic operating condition.

(C10) In any one of the controllers denoted as (C7) through (C9), controlling operation of the electrochemical cell assembly to implement the first diagnostic profile segment may further include controlling the one or more power converters to cause the electrochemical cell assembly to operate in a rest state after controlling the one or more power converters to cause the electrochemical cell assembly to operate at the first predetermined diagnostic operating condition

(C11) In any one of the controllers denoted as (C7) through (C10), (1) the first predetermined diagnostic operating condition may include one of a first rate of charge of the electrochemical cell assembly and a first rate of discharge of the electrochemical cell assembly and (2) the second predetermined diagnostic operating condition may include one of a second rate of charge of the electrochemical cell assembly and a second rate of discharge of the electrochemical cell assembly.

(C12) In any one of the controllers denoted as (C7) through (C10), (1) the first predetermined diagnostic operating condition may include at least one of (i) a first operating current level of the electrochemical cell assembly and (ii) a first operating voltage level of the electrochemical cell assembly and (2) the second predetermined diagnostic operating condition may include at least one of (i) a second operating current level of the electrochemical cell assembly and (ii) a second operating voltage level of the electrochemical cell assembly.

(C13) In any one of the controllers denoted as (C7) through (C10), (1) the first predetermined diagnostic operating condition may include a first operating power level of the electrochemical cell assembly and (2) the second predetermined diagnostic operating condition may include a second operating power level of the electrochemical cell assembly.

(C14) In any one of the controllers denoted as (C1) through (C13), the processing subsystem may be further configured to execute instructions stored in the storage subsystem to (1) obtain one or more measurement characteristics of the electrochemical cell assembly during implementation of each of the plurality of diagnostic profile segments and (2) combine the one or more measurement characteristics of the electrochemical cell assembly obtained during implementation of each of the plurality of diagnostic profile segments to generate a complete measurement set representing characteristics of the electrochemical cell assembly over the complete diagnostic profile.

Changes may be made in the above methods, devices, and systems without departing from the scope hereof. It should thus be noted that the matter contained in the above description and shown in the accompanying drawings should be interpreted as illustrative and not in a limiting sense. The following claims are intended to cover generic and specific features described herein, as well as all statements of the scope of the present method and system, which as a matter of language, might be said to fall therebetween.

What is claimed is:

1. A method for implementing a diagnostic profile for an electrochemical cell assembly, the method comprising:
dividing a complete diagnostic profile for the electrochemical cell assembly into a plurality of diagnostic profile segments, the plurality of diagnostic profile segments including at least a first diagnostic profile segment and a second diagnostic profile segment; and
controlling operation of the electrochemical cell assembly to implement each of the plurality of diagnostic profile segments such that at least the first diagnostic profile segment and the second diagnostic profile segment are implemented during different respective operating intervals of the electrochemical cell assembly.

2. The method of claim 1, wherein:
the different respective operating intervals of the electrochemical cell assembly comprise a first charging interval of the electrochemical cell assembly and a second charging interval of the electrochemical cell assembly; and
the second charging interval of the electrochemical cell assembly is separated in time from the first charging interval of the electrochemical cell assembly by at least one of (i) a discharging interval of the electrochemical cell assembly and (ii) an idle period of the electrochemical cell assembly.

3. The method of claim 2, wherein the second charging interval of the electrochemical cell assembly is further separated in time from the first charging interval of the electrochemical cell assembly by at least one intervening charging interval of the electrochemical cell assembly.

4. The method of claim 1, wherein:
the different respective operating intervals of the electrochemical cell assembly comprise a first discharging interval of the electrochemical cell assembly and a second discharging interval of the electrochemical cell assembly; and
the second discharging interval of the electrochemical cell assembly is separated in time from the first discharging interval of the electrochemical cell assembly by at least one of (i) a charging interval of the electrochemical cell assembly and (ii) an idle period of the electrochemical cell assembly.

5. The method of claim 4, wherein the second discharging interval of the electrochemical cell assembly is further separated in time from the first discharging interval of the electrochemical cell assembly by at least one intervening discharging interval of the electrochemical cell assembly.

6. The method of claim 1, further comprising controlling operation of the electrochemical cell assembly to implement each diagnostic profile segment at a different respective state of charge range of the electrochemical cell assembly.

7. The method of claim 1, wherein:
controlling operation of the electrochemical cell assembly to implement the first diagnostic profile segment comprises causing the electrochemical cell assembly to operate at a first predetermined diagnostic operating condition; and
controlling operation of the electrochemical cell assembly to implement the second diagnostic profile segment comprises causing the electrochemical cell assembly to operate at a second predetermined diagnostic operating condition.

8. The method of claim 7, wherein the second predetermined diagnostic operating condition is different from the first predetermined diagnostic operating condition.

9. The method of claim 7, wherein the second predetermined diagnostic operating condition is the same as the first predetermined diagnostic operating condition.

10. The method of claim 7, wherein controlling operation of the electrochemical cell assembly to implement the first diagnostic profile segment further comprises causing the electrochemical cell assembly to operate in a rest state after causing the electrochemical cell assembly to operate at the first predetermined diagnostic operating condition.

11. The method of claim 7, wherein:
the first predetermined diagnostic operating condition comprises one of a first rate of charge of the electrochemical cell assembly and a first rate of discharge of the electrochemical cell assembly; and
the second predetermined diagnostic operating condition comprises one of a second rate of charge of the electrochemical cell assembly and a second rate of discharge of the electrochemical cell assembly.

12. The method of claim 7, wherein:
the first predetermined diagnostic operating condition comprises at least one of (i) a first operating current level of the electrochemical cell assembly and (ii) a first operating voltage level of the electrochemical cell assembly; and
the second predetermined diagnostic operating condition comprises at least one of (i) a second operating current level of the electrochemical cell assembly and (ii) a second operating voltage level of the electrochemical cell assembly.

13. The method of claim 7, wherein:
the first predetermined diagnostic operating condition comprises a first operating power level of the electrochemical cell assembly; and
the second predetermined diagnostic operating condition comprises a second operating power level of the electrochemical cell assembly.

14. The method of claim 1, further comprising:
obtaining one or more measurement characteristics of the electrochemical cell assembly during implementation of each of the plurality of diagnostic profile segments; and
combining the one or more measurement characteristics of the electrochemical cell assembly obtained during implementation of each of the plurality of diagnostic profile segments to generate a complete measurement set representing characteristics of the electrochemical cell assembly over the complete diagnostic profile.

15. The method of claim 1, wherein controlling operation of the electrochemical cell assembly to implement each of the plurality of diagnostic profile segments such that at least the first diagnostic profile segment and the second diagnostic profile segment are implemented during different respective operating intervals of the electrochemical cell assembly comprises controlling one or more power converters electrically coupled to the electrochemical cell assembly.

16. The method of claim 15, wherein the one or more power converters electrically coupled to the electrochemical cell assembly comprise one or more of (i) an inverter and (ii) a direct-current-to-direct-current (DC-to-DC) converter.

17. A method for implementing a diagnostic profile for an electrochemical cell assembly, the method comprising:
at a first time, controlling operation of the electrochemical cell assembly during a first operating interval of the electrochemical cell assembly to begin implementing a diagnostic profile for the electrochemical cell assembly;
at a second time that is after the first time, controlling operation of the electrochemical cell assembly during the first operating interval of the electrochemical cell assembly to stop implementation of the diagnostic profile before implementation of the diagnostic profile is complete; and
at a third time that is after the second time, controlling operation of the electrochemical cell assembly during a second operating interval of the electrochemical cell assembly to resume implementation of the diagnostic profile.

18. The method of claim 17, wherein controlling operation of the electrochemical cell assembly during the second operating interval of the electrochemical cell assembly to resume implementation of the diagnostic profile comprises resuming implementation of the diagnostic profile at a same place in the diagnostic profile where implementation of the diagnostic profile was stopped at the second time.

19. The method of claim 17, wherein:
the diagnostic profile comprises a plurality of diagnostic profile segments; and
controlling operation of the electrochemical cell assembly during the second operating interval of the electrochemical cell assembly to resume implementation of the diagnostic profile comprises resuming implementation of the diagnostic profile at a beginning of a particular diagnostic profile segment of the plurality of diagnostic profile segments that was being implemented at the second time.

20. The method of claim 17, wherein:
the first operating interval of the electrochemical cell assembly is a first charging interval of the electrochemical cell assembly;
the second operating interval of the electrochemical cell assembly is a second charging interval of the electrochemical cell assembly; and
the second charging interval of the electrochemical cell assembly is separated in time from the first charging interval of the electrochemical cell assembly by at least one of (i) a discharging interval of the electrochemical cell assembly and (ii) an idle period of the electrochemical cell assembly.

21. The method of claim 20, wherein the second charging interval of the electrochemical cell assembly is further separated in time from the first charging interval of the electrochemical cell assembly by at least one intervening charging interval of the electrochemical cell assembly.

22. The method of claim 17, wherein:
the first operating interval of the electrochemical cell assembly is a first discharging interval of the electrochemical cell assembly;
the second operating interval of the electrochemical cell assembly is a second discharging interval of the electrochemical cell assembly; and
the second discharging interval of the electrochemical cell assembly is separated in time from the first discharging interval of the electrochemical cell assembly by at least one of (i) a charging interval of the electrochemical cell assembly and (ii) an idle period of the electrochemical cell assembly.

23. The method of claim 22, wherein the second discharging interval of the electrochemical cell assembly is further separated in time from the first discharging interval of the electrochemical cell assembly by at least one intervening discharging interval of the electrochemical cell assembly.

24. The method of claim 17, wherein the diagnostic profile comprises a plurality of predetermined diagnostic operating conditions of the electrochemical cell assembly corresponding to different respective state of charge ranges of the electrochemical cell assembly.

25. The method of claim 17, wherein controlling operation of the electrochemical cell assembly during each of the first operating interval and the second operating interval comprises controlling one or more power converters electrically coupled to the electrochemical cell assembly.

26. The method of claim 25, wherein the one or more power converters electrically coupled to the electrochemical cell assembly comprise one or more of (i) an inverter and (ii) a direct-current-to-direct-current (DC-to-DC) converter.
